(19) United States
(12) Patent Application Publication
(10) Pub. No.: US 2011/0232630 A1
(43) Pub. Date: Sep. 29, 2011

(54) SOLAR COLLECTOR/WIND DEFLECTOR CONVERSION OF A SOLAR AND WIND CONVERTER

(76) Inventor: Jason Tsao, Torrance, CA (US)

(21) Appl. No.: 13/152,747

(22) Filed: Jun. 3, 2011

(51) Int. Cl. F24J 2/38; F24J 2/04; H01L 31/042; F03D 9/00; H02P 9/04

(52) U.S. Cl. 126/600; 126/678; 126/640; 136/244; 290/55; 290/44

(57) ABSTRACT

An integrated solar and wind hybrid energy generating system is capable of converting a solar collector to a wind deflector to increase wind catching area for the wind turbine during the nighttime and on overcast days and exchangeable between modes of Stirling cycle and reversed Stirling cycle for electricity generation and environmental control. During the sunny days, the system concurrently derives energy from both wind and solar energy sources.

### FIELD OF DISCLOSURE

This disclosure relates to energy conversion, and in particular to wind and solar energy conversion.

### BACKGROUND

Wind energy can be converted into electricity. However, low wind speeds and turbulence in urban and suburban areas, when combined with inherent seasonal and daily variations in wind speed, often use the output of a wind turbine for urban and suburban area to fluctuates. This hampers its ability to generate power efficiently and dependably.

Solar energy can also be converted into electricity. Yet the output of a solar power converter also relies heavily on weather conditions. For instance, many solar panels are designed to only convert solar energy during sunny daylight hours.

### SUMMARY

The invention relates to a hybrid solar and wind energy converter with convertible solar collector/wind deflector. In the absence of enough sun, (e.g., at night and on overcast days) the solar collector can be swung downward and converted into a wind deflector to increase wind-catching area and to enhance wind energy generation of the hybrid solar and wind energy converter.

Some general aspects of the invention relate to systems and methods for providing an integrated, complementary and distributed energy generating system capable of converting wind and solar energy for use with an electrical generator and for use with environmental control. During sunny days, such hybrid systems concurrently derive energy from both wind and sun. During overcast days, and at night, such systems can turn convert a structure ordinarily used as a solar collector into a wind deflector so as to continuously harvest wind energy regardless of the weather conditions. As the peaks of wind flow and sunlight tend to occur at different times of the day and year (for instance, winds tend to be stronger in the winter, precisely when there is less sunlight, and also stronger at night, when there is no sun at all), these two energy sources complement each other. A hybrid system that utilizes both sources can reduce the fluctuation in the combined energy output and produce more on-site electricity in the daytime for urban and suburban areas when electricity demand is usually higher and generate more wind power in the nighttime and on overcast days when there is essentially no solar energy available.

In some embodiments, the system includes means for pivotally mounting the solar collectors, means for tilting the collectors about a horizontal axis, and means for rotating them about a vertical axis, whereby to swing down the solar collector to a downward position for catching the prevailing wind direction into the wind turbine according to the measurements of the anemometer and weather vane data.

The additional wind catching volume that is deflected by a solar collector/wind deflector can be considerable. Depending on wind flow intensity, the system can operate purely as a wind turbine with extra wind catching area when there is no solar radiation available such as during nighttime, rainy or cloudy days. In this mode, the solar collector is converted into a wind deflector and thereby directs extra wind flow onto wind turbine rotors, thus increasing the wind speed and force, thereby resulting in more power output.

One system, for instance, includes a wind powered subsystem having a rotor (e.g. cups, airfoils, blades and vanes) for receiving wind to generate mechanical energy, and a main drive shaft that can be mechanically coupled to the rotor and the drive shaft of an electrical generator for transferring the generated mechanical energy to the electrical generator. Such a system also includes a solar powered subsystem having a solar collector for receiving solar energy to generate thermal energy, a set of thermo-mechanical engines coupled to the solar collector for converting the generated thermal energy into mechanical energy, and a common drive shaft mechanically coupled to the thermo-mechanical engines.

Another system, includes a solar concentrator-supporting medium or frame that is mounted either for orbital travel through a circular path extending horizontally or a polar pole support structure. For orbital rolling, a large solar collector unit is mounted on a supporting medium for swinging or oscillation, during travel of the support, on an axis extending close to the horizontal. For a dual axis polar pole support, a solar collector is mounted to an end of a horizontal beam/axis that is mounted on top of the polar pole/axis.

A solar collector utilizes a solar energy absorbing device (e.g., dishes or troughs) and particular means for supporting the concentrators in a sun tracking mode, specifically a vertical axis and another horizontal axis with respect to which it will rotate in order to track the path traced by the sun. These axes are included as components of a metal profile structure at its top in the coupling between the upper part and the wind turbine, a wheel and groove joint transmitting all the stresses between the upper part and the vertical axis is used, the wheel and groove joint being of the type allowing the axial wind load stress in the upper part of the collectors to be only transmitted in a direction approaching the wind turbine. Not transmitting this wind load stress in the direction of moving away from the central vertical axis is what allows the wheel to be supported on the surface or track even though it is under great wind load so the wheels (e.g., drive wheels and support wheels) cannot be raised above the position in which the upper part of the structure makes the wheel and groove joint contacts with the guide rail that is located at the top rim of the wind turbine.

Dual axis trackers of polar pole support structure type have two degrees of freedom that act as axes of rotation. These axes are typically normal to one another. The single polar axis that is fixed with respect to the ground can be considered a primary axis. The horizontal swing axis that is referenced to the primary axis can be considered a secondary axis.

An azimuth-altitude dual axis tracker of circular rolling structure type has its primary axis vertical to the ground. The secondary axis is then typically normal to the primary axis. One axis is a vertical pivot shaft or a horizontal ring mount that allows the device to be swung to a compass point. The second axis is a horizontal elevation pivot mounted upon the azimuth platform. The lower point of the vertical axis is fixed to the ground (e.g., planar bed plate, concrete girder, metal profile, etc.), such that the tracker rotates with respect to the fixed point, whereas the horizontal axis, perpendicular to the vertical axis, enables the rotation of the collectors possible with respect to it. In the case of more than one collector, the rotation is in a synchronized manner, forming a dual unit. When the sun is low, the solar collector is converted to a wind deflector; and when wind flow changes direction, based on the control signal of the control module (e.g., an anemometer and weather vane), the solar collector/deflector will rotate accordingly to face the wind flow and direct the wind flow substantially to wind turbine rotors that will be moved in the direction of the prevailing wind flow.

Both dual axis trackers of polar pole support structure type and azimuth-altitude dual axis trackers of circular rolling structure type have rotations with respect to the vertical axis or point as well as with respect to the horizontal axis or axes that are controlled by a control unit of the optical type, a heliostat, GPS or a programmable automaton type solar tracking device and/or also by a weather vane and anemometer. Such a controller responds to data from different sensors that provide information concerning, for example, the intensity of the sun's rays, the positions of the solar collectors, the position of the sun, wind speed, and wind direction.

The thermo-mechanical engine subsystem can be an external combustion engine, for instance, having a set of one or more Stirling cycle engines. Each may include a hot zone and a cold zone. A Stirling cycle engine can function in reverse as a heat pump for heating or cooling when the Stirling cycle engines are directly driven by kinetic energy. A radiator type double heat sink anti-freeze Heat Transfer Fluid (HTF) jacket is provided for enhancing the heat exchange rate of the heat absorbing section, the hot zone in Stirling cycle mode that is the cold end in reversed Stirling cycle mode. A water jacket is provided for enhancing the heat exchange rate of the heat dissipating section, the cold zone in Stirling cycle mode which is the hot end in reversed Stirling cycle mode as will be described in detail at a later section of this document.

The radiator type double heat sink anti-freeze HTF jacket makes the Stirling engine's Stirling cycle and reversed Stirling cycle modes change possible and serves as a good heat exchange device for air condition/refrigeration purposes. In nighttime/overcast days, when the solar collector turns into a wind deflector and enhances the wind energy to mechanically move the Stirling cycle into reversed Stirling cycle, then the HTF circulation pump stops and the circulating heat transfer fluid becomes motionless anti-freeze coolant that absorbs heat from the outside environment into the cold end of the reversed Stirling cycle and to be pumped out from the hot end. Without the coolant jacket and radiator type double heat sink, the hybrid system would have difficult providing heat transfer for air condition and/or refrigeration and heat transfer from solar absorber with only one Stirling engines with two different cycles because only the cold end itself of the reversed Stirling cycle can only absorb heat from one kind of medium (e.g., air for air condition/refrigeration or heat transfer fluid for solar heat input) but not from both. This coolant jacket feature not only solve the problem of absorbing heat through two kinds of medium (e.g., air and fluid) but also provide an integrated and complementary energy generating system capable of converting wind and solar energy into energy for use with at least one of air-conditioning, refrigeration, space-heating, hot water supply and electricity generation. It not only reduces the cost of additional set of Stirling engines but also cut down the maintenances fee greatly.

When the Heat Transfer Fluid (HTF) circulation pump is off and the system is in reversed Stirling cycle mode, the anti-freeze heat transfer fluid stops flowing and stays in the radiator type double heat sink HTF jacket and transfers heat into a cold end of the reversed Stirling engine from outside a targeted area. The radiator-type double heat sink anti-freeze HTF jacket is configured and capable of providing both heat transfer processes through either HTF circulation (solar heat input) in Stirling cycle mode or HTF non-circulation (heat absorption from outside targeted area) in the reversed Stirling cycle mode within the same thermo-mechanical engine.

In operation the heat pump removes heat from outside air and delivers this heat into the home. When the temperature falls below about 45 F and the humidity is high enough the moisture condenses on the heat pump fins. If the system runs, ice can build up and hamper the heat pump's ability to move air through the fins, thus impeding heat exchange. The anti-freeze HTF (coolant) jacket with radiator type double heat sink increases the heat transfer area greatly and controlled periodical circulation of the HTF that reduces the accumulation of the ice and frost on the fins of the heat sink, thus providing an improvement over a conventional heat pump.

An interconnection subsystem is provided for disengageably coupling the shafts for combining the mechanical energy generated by the wind and solar powered subsystems to be transferred to the electrical generator or to carry out heat transfer. As used herein, two constituent structures of an apparatus are “disengageably coupled” if they are configured to be coupled and decoupled during normal operation of the apparatus.

One embodiment of the interconnection subsystem includes a set of pulleys and V-belts, a mechanical clutch, an electromagnetic clutch or a variator clutch. The interconnection subsystem may further include a control module for generating the control signal for activating the interconnection subsystem in response to environmental and system conditions, for instance, wind conditions, sun conditions, room or refrigerator temperature, and temperature conditions in the cold zone insulated enclosure and hot zone insulated enclosure in reversed Stirling cycle mode during nighttime and overcast days. In some examples, the control module includes an anemometer, temperature, motion and position sensors for detecting the temperature and position of the system and thermostats in the building or refrigerator space.

Another aspect of the systems and methods disclosed herein relates to methods that include obtaining measurements characterizing an environmental condition (e.g., a room or refrigerator temperature condition, a wind condition, a sun condition), and determining whether an activation condition is satisfied according to the obtained measurements. Upon satisfaction of the activation condition, the shaft of the wind turbine is engaged to the shaft of the Stirling engines for transferring the wind energy into it and converts the Stirling engines into reversed Stirling cycle engines (Stirling refrigerators or heat pumps). The shaft is also disengaged from the shaft of the electrical generator to stop transfer of the mechanical energy generated by the wind power subsystem to an electrical generator.

In some practices, the invention also includes determining whether a deactivation condition is satisfied according to the obtained measurements. Upon satisfaction of the deactivation condition, the driving shaft of the wind power subsystem is disengaged from the shaft of the reversed Stirling cycle engines to stop transfer of the mechanical energy generated by the wind power subsystem to the Stirling refrigerators/heat pumps and is engaged to the shaft of the electrical generator to transfer of the mechanical energy generated by the wind power subsystem to an electrical generator, and vice-versa.

In some examples, the activation condition is associated with a first threshold temperature, and the deactivation condition is associated with a second threshold temperature in the system or targeted area.

In another aspect, the invention features an apparatus for selectively converting solar and/or wind energy for selectively powering an electrical generator and/or a thermo-mechanical engine. Such an apparatus includes a hybrid-powered subsystem including a wind-powered subsystem and a solar-powered subsystem.

The wind-powered subsystem includes a rotor for receiving wind to generate mechanical energy; a convertible structure that transitions between being a wind deflector and being a solar collector; a driving mechanism for the convertible structure; and a first shaft for providing a mechanical coupling for the rotor to transfer the generated mechanical energy.

The solar-powered subsystem includes a solar collector for receiving solar energy to generate thermal energy; a solar collector-supporting frame structure. The solar-powered subsystem also includes stacked thermo-mechanical engines with exchangeable thermo-mechanical/reversed thermo-mechanical engines mode either coupled to the wind-powered subsystem for selectively converting the mechanical energy generated by the wind-powered subsystem into energy for controlling temperature in a space or coupled to the solar collector for converting the generated thermal energy into mechanical energy; and a second shaft mechanically coupled to the thermo-mechanical engines; and a third shaft mechanically coupled to an electrical generator.

The apparatus further includes an interconnection subsystem configured for disengageably coupling a pair of shafts, wherein the pair of shafts is selected from the group consisting of the first shaft and the second shaft, and the first shaft and the third shaft.

In some embodiments, the solar powered subsystem further includes a pair of polar pole support structures mounted adjacent to a periphery of the rotor of the wind powered subsystem. Among these embodiments are those in which the polar pole support structure includes: a first single polar column member positioned adjacent to a periphery of the rotor; and a second single polar column member positioned adjacent to a periphery of the rotor diametrically opposite from the first single polar column member. In some of these embodiments, the polar pole support structure further includes a first horizontal support beam mounted on top of the first vertical polar pole support structure, the first horizontal support beam having a swivel at an outside edge thereof to cause the solar collector to rotate horizontally and/or vertically; and a first counter weight at an opposite end of the first horizontal support beam, the counter weight to counter balance the solar collector to rotate horizontally and/or vertically; a second horizontal support beam mounted on top of the second vertical polar pole support structure, the second horizontal support beam having a swivel at an outside edge thereof, the solar collector to rotate horizontally and/or vertically; and a second counter weight at an opposite end of the second horizontal support beam, the counter weight to counter balance the solar collector to rotate horizontally and/or vertically; wherein the first and second single polar pole support and horizontal beam structure cooperate to direct wind flow toward a desired region of the rotor in response to changes in wind direction.

In yet other embodiments, the solar powered subsystem further includes a circular rolling supporting rail track structure mounted around a periphery of the rotor of the wind powered subsystem. In some of these embodiments, the circular rolling supporting rail track structure includes a solar collector-supporting frame structure that is mounted for orbital travel through a circular path extending horizontally. Among these are embodiments in which the solar collector-supporting frame structure further includes: a horizontally rotating azimuth circular rail track mounts; vertical frames on each side that hold elevation trunnions for the solar collector and integral solar absorber/driving mechanisms thereof; and a horizontal layout rolling wheel that moves in a grove rail on top of and around the wind turbine to support wind load stress on the supporting frame.

In additional embodiments, the solar powered subsystem includes circulation systems for respectively circulating anti-freeze heat transfer fluid through a heat absorbing section and cooling agent through a heat dissipating section in the exchangeable thermo-mechanical engine mode or reversed thermo-mechanical engine mode. In some of these additional embodiments, the circulation system includes a thermally insulated closed loop circulation system; a radiator type double heat sink heat transfer fluid jacket; a fluid reservoir for containing the heat transfer fluid; and a pump for pumping the anti-freeze heat transfer fluid contained in the fluid reservoir through a first conduit toward a heat source to be heated and subsequently through a second conduit toward a hot zone of the thermo-mechanical engine, whereby the anti-freeze heat transfer fluid exchanges heat in the hot zone of the thermo-mechanical engine when the pump is on and in Stirling engine mode; and wherein when the pump is off and the system is in reversed Stirling engine mode the anti-freeze heat transfer fluid stops flowing and stays in a cold end of the radiator type double heat sink heat transfer fluid jacket and transfers heat into the cold end of the reversed Stirling engine from outside a targeted area, the radiator type double heat sink being configured to prevent accumulation of ice and frost on the heat sink.

Yet other embodiments include those in which the solar powered subsystem further includes a set of one or more solar panels coupled to the solar collector for generating additional electricity to power one or more power consumption devices. Among these embodiments are those in which the solar panel includes triangular wind deflectors to cover top and bottom sections of gaps between two joined solar dishes.

Additional embodiments include those in which the interconnection subsystem includes a set of pulleys and one or more V-belts for selectively coupling the set of pulleys. Among these are embodiments that further comprise a control module for generating a control signal for causing movement for controlling the interconnection system, wind powered subsystem, solar powered subsystem and solar collector/wind deflector supporting structures in response to environmental conditions. Among these embodiments are those in which the control module is configured to respond to environmental conditions that includes a wind condition, those in which the control module is configured to respond to environmental conditions that includes an extent of solar illumination, and those in which the control module is configured to respond to environmental conditions that includes a temperature, and those in which the control module includes an anemometer, weather vane, and one or more temperature, motion and position sensors and thermostats.

Yet other embodiments are those in which the interconnection subsystem further includes one of a mechanical clutch, an electromagnetic clutch and variator clutch, those in which the solar powered subsystem further includes a solar tracking component for obtaining measurements of the sun's rays and for directing the solar collector to a desired orientation relative to the sun's rays based on the obtained measurements, those in which the wind powered subsystem includes a horizontal-axis turbine and a vertical-axis turbine, and those in which the solar powered subsystem further includes a second circulation system for circulating cooling agent to maintain a low temperature of the heat dissipating section, the heat dissipating section being a cold zone in thermo-mechanical engine mode and a hot end in reversed thermo-mechanical engine mode.

Embodiments of various aspects of the system disclosed herein may include one or more of the following features and advantages.

For instance, as a result of the innate synergy between the various assemblies in this air-conditioning/refrigeration, space-heating, hot water and electricity generation with solar and wind hybrid energy converting system, the cooled air and heat output is generated by the same Stirling engines (e.g., in either Stirling cycle mode or reversed Stirling cycle mode) in a much more efficient way than any of these components alone (e.g., Stirling refrigerator, Stirling heat pump, wind turbine, solar Stirling engines, solar collector, battery bank, electrical generator etc.). Also, the wind deflector enhanced wind powered reversed Stirling cycle engines system can provide cooled air or heat or complementary electricity throughout overcast days and nighttime as an integrated, direct driven and self contained unit even when solar energy is not available. This reduces the cost of electricity generation and the need for high volume battery packs that can be both expensive and undependable.

In some examples, the multiple reversed Stirling cycle engines can be equipped with a heat exchanger that surrounds the heat absorbing section and the heat dissipating section with a forced air and fin system. The reversed Stirling cycle engines cold end and hot end heat exchanger insulated enclosure housings are respectively connected to the specific inbound insulated air duct and outbound insulated air duct. The heat sinks undergo suction from the spinning rotors of the wind turbine, thus assuring constant airflow for heat convection. The constant movement of air enhances heat dissipation/heat absorption and provides better performance than un-blown heat sinks

An additional advantage to having a direct drive between the hybrid solar and wind power sources and the system is that energy storage and conversion become unnecessary. This eliminates a major source of inefficiency. As a result, the direct driven Stirling cycle engines (e.g., in either Stirling cycle mode or reversed Stirling cycle mode) are useful for making air-conditioning/refrigeration, space-heating and electricity generation systems more efficient in operation, more lightweight in construction, more compact for installation, and less expensive to own.

The whole system can be mounted in vertical, horizontal, or other aligned operational positions and fit inside of an attic, on a rooftop or on a stand-alone pole.

The solar collector may include an array of one or more collectors such as parabolic reflectors, parabolic troughs, compound parabolic collectors (CPCs), evacuated solar tubes, photovoltaic panels and Fresnel lens, some of which are configured for concentrating sunrays on an absorber to heat the heat transfer fluid circulated in the thermo-mechanical engine.

The wind-powered subsystem may include a vertical-axis turbine and a horizontal-axis turbine.

In some embodiments, a wind powered subsystem further includes a Darrieus type turbine; two Savonius type turbines, and a Giromills Cycloturbine.

The solar powered subsystem may further include a set of one or more solar panels coupled to the solar collector for generating additional electricity to power one or more power consumption devices in the interconnection subsystem, solar collector/wind deflector supporting structure with diving mechanisms, wind or the solar powered subsystem.

The integrated and flexible design of the system does not require sophisticated electronic device and a high degree of precision in manufacturing. Since materials of high thermal tolerance are not necessarily required for the majority of the design, the solar energy collector, concentrator and supporting frame structure can largely use high strength, non-corrosive, shock absorbent, vibration dampening and lightweight advanced composite (glass fiber and carbon fiber). The wind collector incorporates with the high strength and lightweight advanced composite (S glass fiber, high modulus carbon fiber and Kevlar fiber) cups, airfoils, blades, rotors or vanes to generate electricity. Such an integrated structure is also not susceptible to damage by strong winds, temperature, moisture and other elements. In some examples, the filament wound tubing frame structure, the compressed mold enclosures of the Stirling engines, the reflective film of solar collectors, and the Fresnel lens can be fabricated using industrial grade aluminum, aluminum coating reflective Mylar film, and/or acrylic plastic, thereby reducing the manufacturing cost.

A wind rose is a graphic tool used by meteorologists to give a succinct view of how wind speed and direction are typically distributed at a particular location and over a specified time period. According to wind rose, the prevailing wind direction for most area is either land to sea/sea to land or valley to mountain/mountain to valley. That means the polar pole supporting type solar collector/wind deflector will catch most of the wind by turning its dual wind deflector to two opposite directions of prevailing wind direction during daytime and nighttime to maximize the wind catching efficiency.

In some embodiments, the wind turbine generator includes at least two rotors (e.g. cups, vanes, blades or airfoils). The use of a greater number of turbine rotors may provide a lower tip speed and lower noise emission and higher efficiency, but can also be more difficult to start or too weak to produce electricity to meet house's electrical load. In such cases, it may be desired to provide an additional wind power from solar collector/deflector to accelerate the rotor to a higher velocity at which the rotor can produce positive torque and generate more electricity.

In some implementations, the solar collector is located on top of the wind turbine so the wind rotor would not be obstructed from direct access to the prevailing wind. Because the systems use modular design and are structure balanced, it would also be easy to scale up the system by adding more thermo-mechanical engines or wind turbines or enlarging the size of solar collector and wind turbine. As the wind power increases as a function of the cube of the surface area of the rotor as well as a function of the height of wind turbine, wind forces placed on the assemblies can be fully utilized as the system is either enlarged to create more power or use solar collector as a wind deflector to increase wind catching area. Furthermore, in practical applications, such systems can be located at sites of higher location such as rooftop or stand alone in a backyard or a parking lot, and be suitable for both residential and commercial uses.

Other features and advantages of the invention are apparent from the following description, and from the claims.

### DESCRIPTION OF DRAWINGS

FIG. 1 is a block diagram of a hybrid system with features of a convertible solar collector/wind deflector for generating energy from solar and wind energy sources.

FIG. 2 is a schematic diagram of the hybrid system of FIG. 1 configured in solar collector/Stirling engine mode and wind deflector/reversed Stirling engine mode.

FIGS. 3A and 3B with the center spilt lines to easily illustrates the cold end of the reversed Stirling engine, a heat absorbing section is as same as the hot zone in Stirling cycle mode and the hot end of the reversed Stirling engine, a heat dissipating section is also as same as the cold zone in Stirling cycle mode.

FIGS. 4A and 4B show the Stirling cycle and reversed Stirling cycle modes and coolant jacket processes changes during daytime and nighttime.

FIGS. 5A and 5B are side views of various configurations of the hybrid system in solar collector/Stirling engine mode. The auxiliary gas burner is either on to add heat to the system or off to standby. The anti-freeze coolant pump is on and the Stirling engines are coupled with wind turbine with mechanical output.

FIGS. 6A and 6B are side views of various configurations of the hybrid system, with FIG. 6A showing the system in wind deflector/Stirling engine mode with mechanical output and the auxiliary gas burner is on to add heat to the system and FIG. 6B showing the system in wind deflector/reversed Stirling engine mode with environmental control and the auxiliary gas burner is off to standby. The anti-freeze coolant pump is off

FIG. 6C illustrates the radiator type double heat sink anti-freeze heat transfer fluid stays in the heat absorbing area (cold end) of the close loop circulation system when the pump is off and in reversed Stirling engine mode and environmental control. It also illustrates another circulation system of the radiator type double heat sink cooling agent flows through the heat dissipating area (hot end) in reversed Stirling engine mode.

FIG. 6D illustrates the radiator type double heat sink anti-freeze heat transfer fluid stays in the heat absorbing area (cold end) of the close loop circulation system when the pump is off and in reversed Stirling engine mode and refrigeration. It also illustrates another circulation system of the radiator type double heat sink cooling agent flows through the heat dissipating area (cold zone) in Stirling engine mode.

FIGS. 7A1, 7A2, 7B and 7C illustrate the couplings between an auxiliary motor, Stirling/reversed Stirling engines, a wind turbine shaft and electrical generator in nighttime/overcast days and daytime/sunny days.

FIG. 8 is a flow diagram of an operation of the hybrid system with features of convertible solar collector/wind deflector of FIG. 1.

FIG. 9 is a side view and schematic diagram of the convertible solar collector/wind deflector supporting structure of a hybrid system that can be wheel supported on top of wind turbine and rolling in the grove track on ground.

FIG. 10 is a schematic diagram of the circular movement solar collector/wind deflector supporting structure of a hybrid system with wind turbine.

FIG. 11 illustrates two modes of the circular solar collector/wind deflector structure that can be coupled to a wind turbine.

FIG. 12 shows sequential movements of the circular solar collector of azimuth from sunrise to sunset.

FIG. 13 illustrates alignment of the circular solar collector/wind deflector structure in wind deflector mode with wind of various directions.

FIG. 14 shows a Wind Rose plot of wind speed and direction at a particular location. It shows the major wind blow directions are opposite during a day.

FIG. 15 is a schematic diagram of the dual polar pole solar collector/wind deflector supporting structure of a hybrid system with wind turbine.

FIG. 16A illustrates two modes of the dual polar pole solar collector/wind deflector structure that can be coupled to a wind turbine.

FIG. 16B illustrates two modes of the central single polar pole solar collector/wind deflector structure that can be coupled to a wind turbine.

FIG. 17 shows sequential movements of the dual polar pole solar collector of azimuth from sunrise to sunset.

FIG. 18 illustrates alignment of the dual polar pole solar collector/wind deflector structure in wind deflector mode with wind of various directions.

FIG. 19 shows three operational positions of the circular solar collector/wind deflector structure and the polar pole solar collector/wind deflector structure of the hybrid system.

FIG. 20 shows various types of layouts of the solar collector/wind deflector supporting structure of a hybrid system, including a solar dish, a solar trough, a solar panel and solar evacuated tubes.

FIG. 21 shows a perspective view of various types hybrid systems that can be mounted on flat rooftop, pole and other free standing position and the use of solar panels to generate additional electricity to supply the electric requirements of a hybrid system or to combine the electrical currents via electrical coupling means.

FIG. 22 shows various types of wind turbine embodiments, including a Darrieus type turbine, a Savonius type turbine, stacked Savonius type turbines, and a Giromills Cycloturbine.

FIG. 23 shows various types of Stirling/reversed Stirling cycle engine layouts, including an Alpha type, a Beta type, and a Gamma type.

### DETAILED DESCRIPTION

### Overview

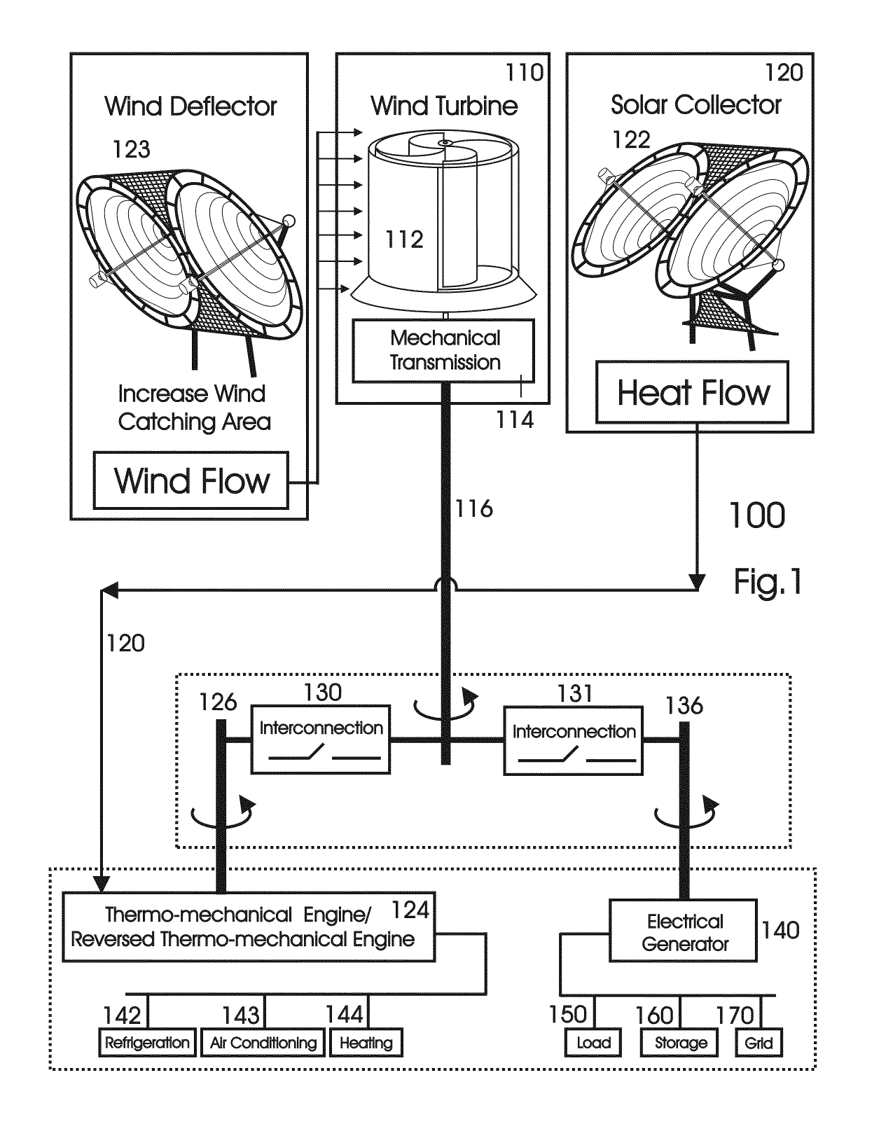

Referring to FIG. 1, a hybrid system 100 is configured for generating electricity from both wind and solar energy sources. The system 100 includes a wind powered subsystem 110 having a rotor 112 (e.g., a wind turbine) for receiving wind to generate mechanical energy, and a mechanical transmission mechanism 114 (e.g., a set of gears and/or shafts) for transmitting the generated mechanical energy to a main shaft 116 of the wind powered subsystem 110 to drive an electrical generator 140. Depending on the particular applications, the electrical generator 140 can be a synchronized generator or an asynchronized generator, and the electrical output of the generator can be used by a load 150 (e.g., home appliances), be stored in a storage unit 160 (e.g., a set of batteries), or be provided to an electrical grid 170.

The hybrid system 100 also includes a solar powered subsystem 120 having a solar collector 122 (e.g., a parabolic dish) for converting solar energy into heat, a wind deflector 123 which can be converted from the solar collector 122 and a set of thermo-mechanical/reversed thermo-mechanical engine 124 (e.g., an external combustion engine) for subsequently converting heat into mechanical energy to drive a main shaft 126 of the solar powered subsystem 120 thus driving an electrical generator 140 in day time/sunny days. In nighttime/overcast days the kinetic power generated from wind turbine 112 will turn thermo-mechanical engine 124 into reversed thermo-mechanical mode by coupling shafts 116 and 126.

The system 100 also includes refrigeration 142, air-conditioning 143 and space-heating 144 subsystems having stacked reversed Stirling cycle engines 124 (e.g., Stirling cycle heat pumps or refrigerators) for harnessing kinetic energy of wind turbine for air-conditioning, refrigeration, or space-heating.

To utilize the energy generated by the solar powered subsystem 120, an interconnection subsystem 130 is provided for disengageably coupling the main shaft 126 of the solar powered subsystem to the main shaft 116 of the wind powered subsystem.

Also, to utilize the energy generated by the solar and wind combined powered subsystem 110 and 120, an interconnection subsystem 131 is provided for disengageably coupling the main shaft 126 of the electrical generator to the main shaft 116 of the wind powered subsystem. As a result, the mechanical energy derived respectively from wind and solar sources is combined together to power the electrical generator 140 through drive shaft 136.

Generally, the wind powered subsystem 110 operates regardless of weather conditions, but the amount of electrical energy generated from wind may depend on local wind speed. The solar powered subsystem 120, on the other hand, is selectively activated, for instance, based on solar intensity. In daytime and on sunny days during the operation of the solar powered subsystem 120, when shaft 126 is coupled to shaft 116, the input to the electrical generator 140 is increased as a result of the superposition of the mechanical energy derived from the two subsystems 110 and 120. In nighttime and overcast days the solar collector 122 of the solar powered subsystem 120 is converted to wind deflector 123 and during the operation of the wind powered subsystem 110, when wind deflector 123 increases wind catching area and directs wind into rotors of wind turbine 112, the input to the wind powered subsystem 110 is increased as a result of the superposition of the wind energy derived from the two subsystems 110 and 120. When wind turbine drive shaft 116 is coupled to shaft 126 of the Stirling engine 124S, the solar powered Stirling cycle engine is converted into reversed Stirling cycle 124R (i.e. Stirling refrigerator/heat pump) that is configured for air-conditioning/refrigeration, space-heating from wind energy sources as a result of the superposition of the kinetic energy derived from the wind powered subsystems 110.

Thus, the hybrid system 100 can produce more electricity when the two subsystems 110 and 120 operate in a complementary mode. On sunny days the main drive shaft 116 of the wind powered subsystem 110 and the solar powered subsystem 120 are coupled to drive shaft 136 of the electrical generator 140. This enables the system 100 to generate electricity. The system 100 can also operate solely as a wind powered system when there is no solar radiation available such as at night or on rainy and/or cloudy days.

In such cases, the solar collector 122 will be converted into a wind deflector to increase wind-catching area of the wind turbine and inducing the rotor 112 to spin by the wind alone. With its extra wind-catching area, the hybrid system 100 can also produce more electricity at night and on overcast days when the wind powered subsystems 110 and the wind deflector 123 cooperate.

The following description includes discussions of various embodiments of the hybrid system with convertible solar collector/wind deflector 100 of FIG. 1 and mechanisms by which the system can operate.

Exemplary Embodiments of Hybrid Energy Conversion Systems with Convertible Solar Collector/Wind Deflector

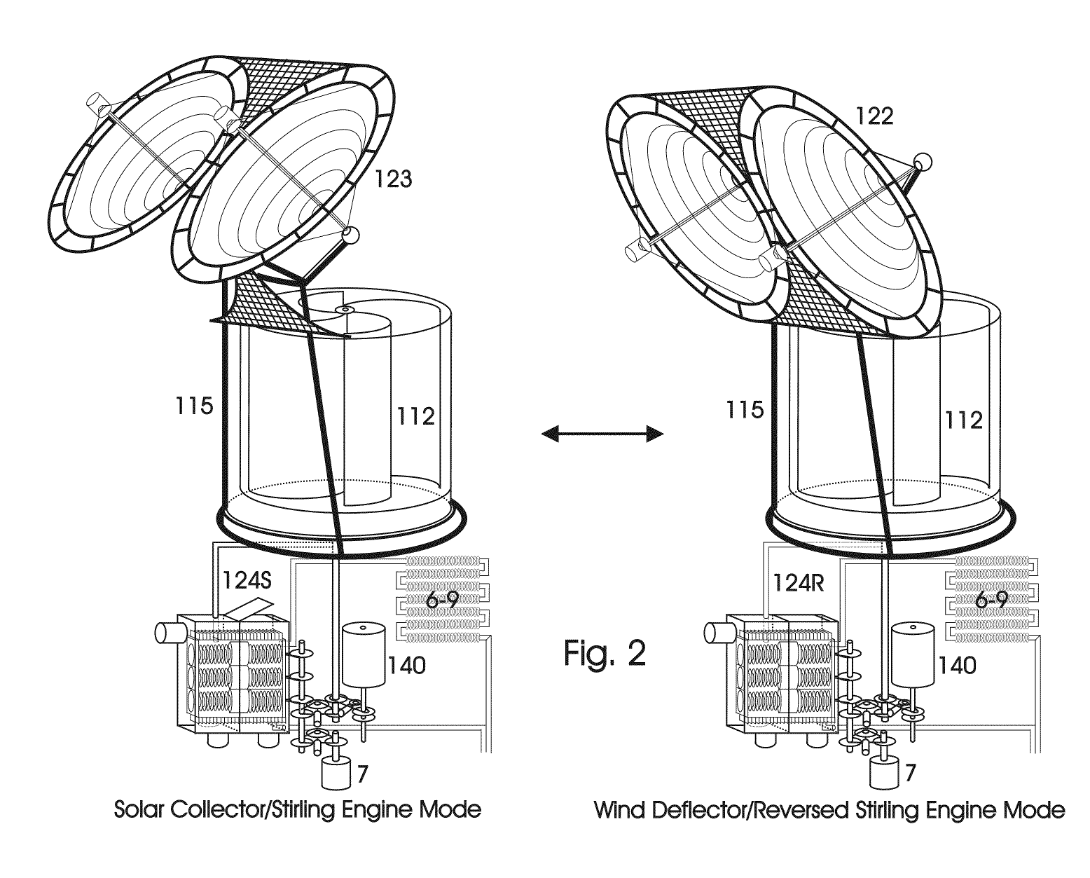

FIG. 2 shows one embodiment of the hybrid system with features of convertible solar collector/wind deflector 100 of FIG. 1 configured in generating energy from solar and wind energy sources and environment control.

### Stirling/Reversed Stirling Engine

A Stirling engine is a type of external combustion engine that can convert heat into mechanical energy (e.g., in the form of driving power) by continuously heating and cooling a captive working gas. The reversed Stirling cycle engines are directly driven by the kinetic energy that uses mechanical energy to extract heat from a target volume (i.e., a dwelling or refrigerator).

This system includes a solar collector 1, a set of stacked Stirling engines/reversed Stirling engines 124 (a type of thermo-mechanical engine), a wind turbine 112, an electrical generator 140, an auxiliary starter motor 7, and a heat sink 6-9.

A heat absorber of the solar collector 122 receives solar energy and generates heat (e.g., up to 400 Celsius) to power the multiple Stirling engines 124S to apply a complementary force to rotate drive shaft 126 and electrical generator 140, thereby generating electricity concurrently. In order to convert the mechanical energy to electrical energy, a mechanical-to-electrical converter, for instance, the electrical generator 140, is used. The generator 140 is mechanically coupled by the drive shaft 136 to the drive shaft 116 of the wind turbine 112 to produce useful output. If desired, the electricity generated by the generator 140 is stored in an electrical energy storage device, such as battery banks 160, prior to being used by a consumer. The solar collector 122 is converted to a wind deflector 123 at night and on overcast days to increase wind-catching area and to direct the wind flow onto wind turbine rotors 112, which can also increase the wind flow and force, thereby resulting in more power output.

In some applications, the vertical alignment shown in FIG. 2 is adopted so that wind, regardless of its direction, can always cause rotation of the wind turbine rotors 112 without adjustment of turbine axis 116. As shown in FIG. 2, the whole hybrid system can be self-contained in a small footprint.

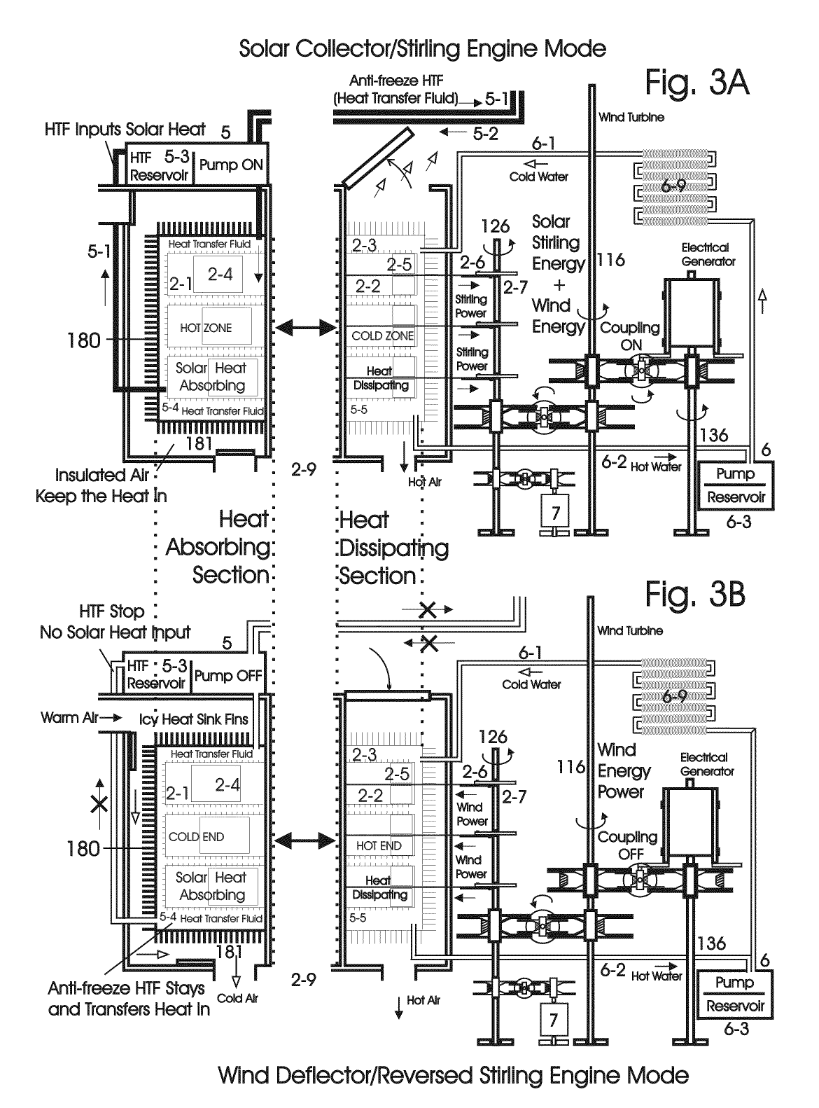

Referring to FIGS. 3A and 3B, one example of the Stirling engine 124 operates on the principle that a working gas expands when heated and contracts when cooled. The Stirling engine includes a hot zone 2-1, a heat absorbing section and a cold zone 2-2, a heat dissipating section, an anti-freeze HTF jacket 180, an anti-freeze HTF jacket radiator type heat sink 181, a water jacket 2-3, a radiator type heat sink 5-4 and 5-5, a displacer piston 2-4, a power piston 2-5, a crankshaft 2-6, a flywheel 2-7, a jointed drive shaft 2-8 and a regenerator 2-9.

The center spilt shown in FIGS. 3A and 3B illustrates the cold end of the reversed Stirling engine. A heat absorbing section is a hot zone when the engine is in Stirling cycle mode and a cold end when the engine operates as a reversed Stirling engine 124R. A heat dissipating section is a cold zone when the engine is in Stirling cycle mode and a hot end when the engine is in reversed Stirling cycle mode.

On sunny days, when operating in solar collector/Stirling engine mode, a heat transfer fluid is circulated by HTF pump 5 and heats up the hot zone 2-1 of the Stirling engine, the expanding working gas will force the displacer piston 2-4 and the power piston 2-5 into cyclic motions. The regenerator 2-9 is generally located between hot zone 2-1 and cold zone 2-2 of the Stirling engine and includes a matrix of fine wire. The mechanical linkages of crankshafts 2-6 rotate flywheels 2-7 that are affixed to the jointed drive shaft 2-8 of the multiple stacked Stirling engines 2. The hot zone 2-1 of the engine includes an anti-freeze HTF jacket 180, an anti-freeze HTF jacket radiator type heat sink 181 (e.g., a heat absorbing device) with fins and/or other means of increasing the surface area that covers the hot zone and a radiator type heat sink 5-4 (e.g., a heat absorbing device) with fins and/or other means of increasing the surface area that covers the hot zone as shown in FIG. 3A.

At night and on overcast days, when operating in wind deflector/reversed Stirling engine mode, HTF pump 5 stops circulation. Consequently, there is no heat transfer fluid to heat up the hot zone 2-1 of the Stirling engine. The input kinetic energy from wind-powered subsystem 110 will then force the displacer piston 2-4 and the power piston 2-5 into cyclic motions. The cold end 2-1R of the reversed Stirling engine 124R, (a heat absorbing section) fills with anti-freeze HTF and starts to absorb heat from outside environment through the outer heat sink 181 then transfer heat through the inner heat sink 5-4 into the cold end of the reversed Stirling engine 124R. The cold end 2-1R of the reversed Stirling engine includes an anti-freeze HTF jacket 180, an anti-freeze HTF jacket radiator type heat sink 181 (e.g., a heat absorbing device) with fins and/or other means of increasing the surface area that covers the cold end and a radiator type heat sink 5-4 (e.g., a heat absorbing device) with fins and/or other means of increasing the surface area that covers the hot zone as shown in FIG. 3B.

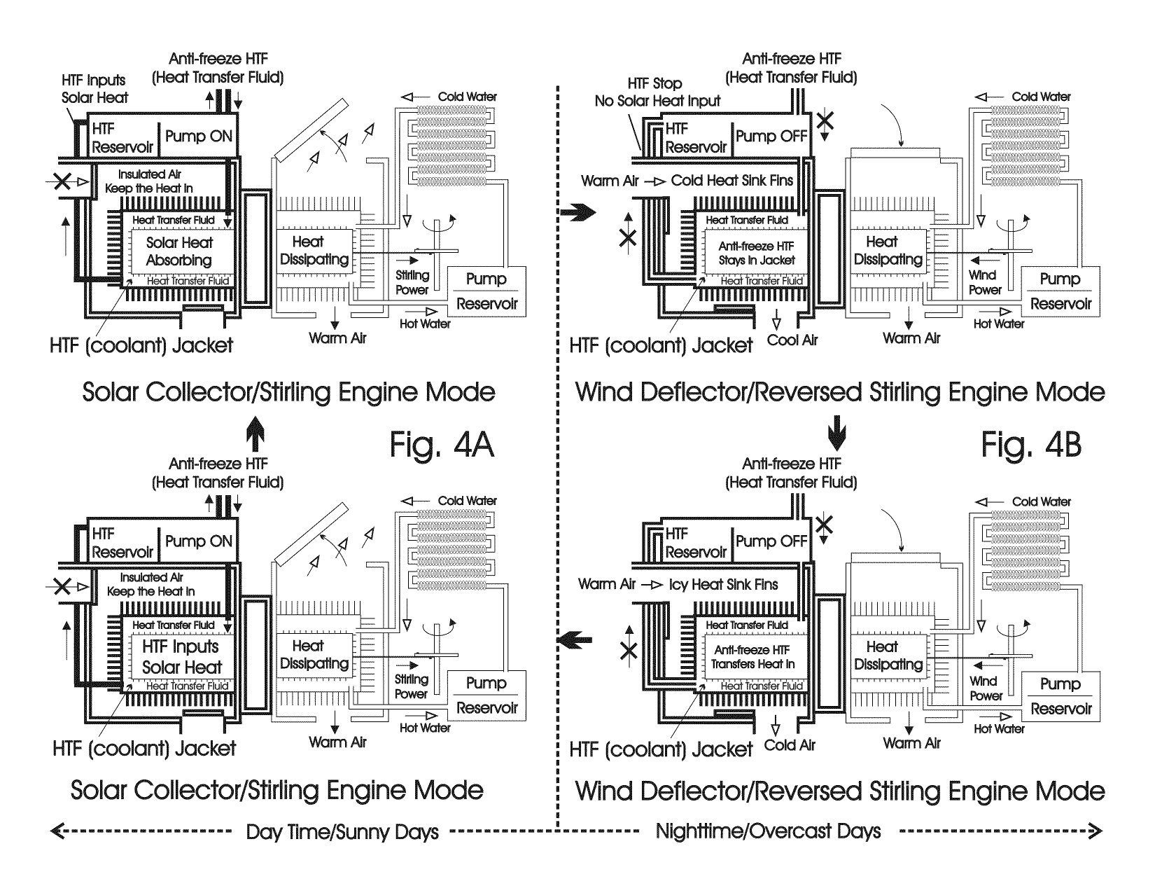

FIGS. 4A and 4B show the four different coolant jacket and pump processes and Stirling cycle modes during daytime and nighttime.

### Radiator Type Double Heat Sink Anti-freeze HTF Jacket Closed Loop Circulation System

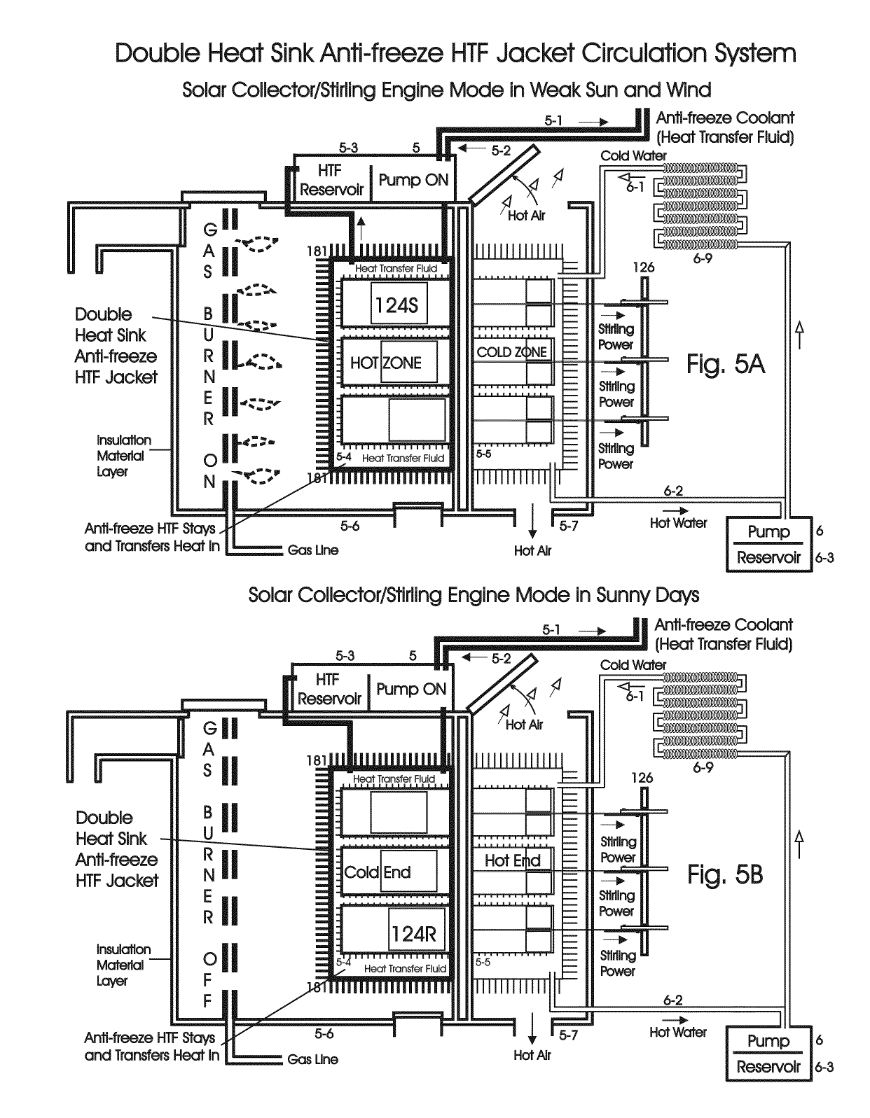

Now referring to FIGS. 5A and 5B, on a sunny day, the heat transfer fluid is heated (e.g., up to 400 Celsius) in absorber of the solar collector 122 and the heated HTF passes a downstream conduit 5-2 that connects to the hot zone 2-1 of the multiple Stirling engines set 124S. Following heat exchange inside the multiple stacked Stirling engines 124S, the heat transfer fluid is pumped through an upstream conduit 5-1 back to the absorber to complete a closed heating cycle as indicated in FIG. 5. The high heat (e.g., up to 400 Celsius) passes through the anti-freeze HTF jacket 180 that surrounds the hot zone 2-1 of the multiple Stirling engines, which is wrapped with the absorbing heat sink 5-4 in the hot zone of the Stirling engines in turn and with stepping down heat exchange rate thus the Stirling engines can fully utilize the heat to maximize the output of power. When the sun is weak the auxiliary gas burner adds heat to the system as shown in FIG. 5A. Otherwise, it remains on standby as shown in FIG. 5B. The still air trapped in the hot zone enclosure 5-6 serves as a good insulation of heat and the hot zone enclosure 5-6, rotary pump 5, conduits 5-1, 5-2, the heat transfer fluid reservoir tank 5-3 and the heating cycle system are double sealed and insulated to reduce the heat loss and to enhance the efficiency of the Stirling engines. The heat transfer fluid closed cycle circulation system including rotary pump 5, conduits 5-1, 5-2, the heat transfer fluid reservoir 5-3 that is located above the multiple Stirling engines 124S, an anti-freeze HTF jacket 180, an anti-freeze HTF jacket radiator type heat sink 181, a hot zone enclosure 5-6 and a radiator type heat sink 5-4 of the hot zone 2-1 of the Stirling engines is shown in FIGS. 4A, 5A and 5B.

Another cooling agent circulation system with a semi-closed cycle includes a rotary pump 6, conduits 6-1, 6-2, a water jacket 2-3 surrounding the cold zone 2-2 of the multiple Stirling engines, a radiator type heat sink 5-5 of the cold zone 2-2 of the Stirling engines 124S, a cold zone enclosure 5-7, and a radiator type heat sink 6-9 (e.g., a metal structure with fins) of the cooling agent upstream conduit 6-1 as shown in FIG. 4A, 5A and 5B.

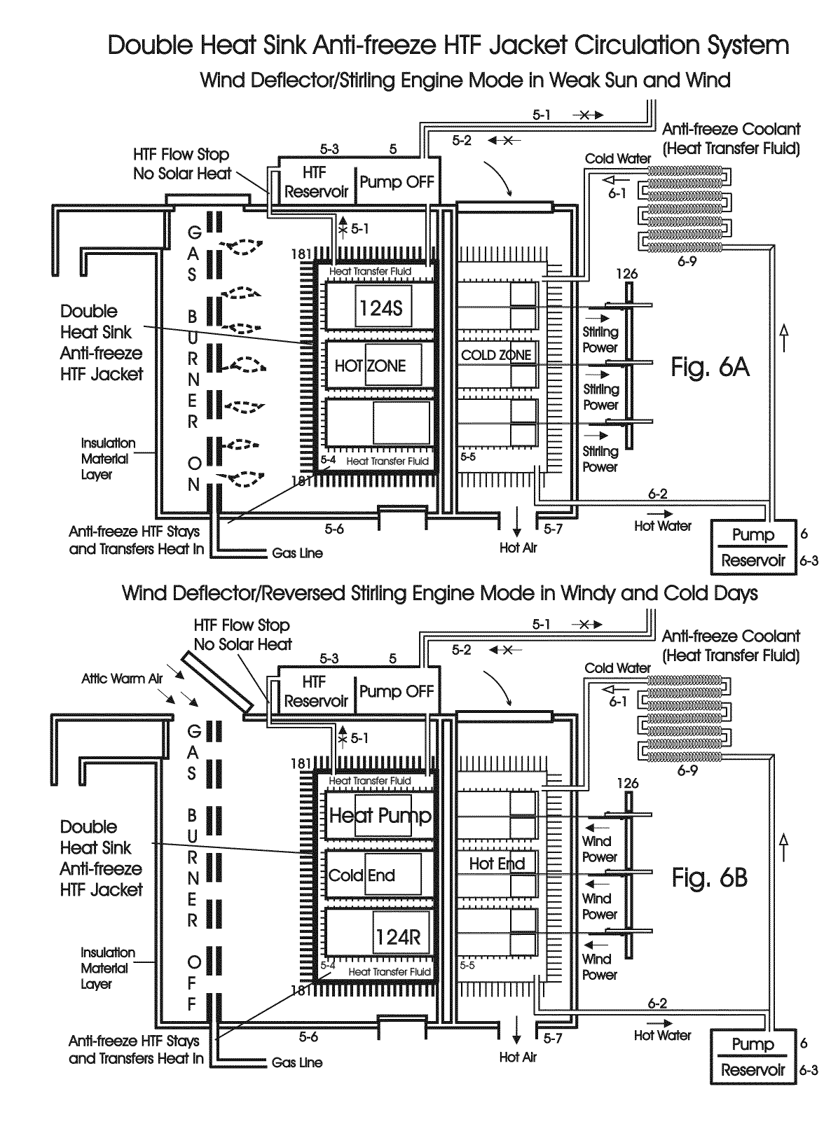

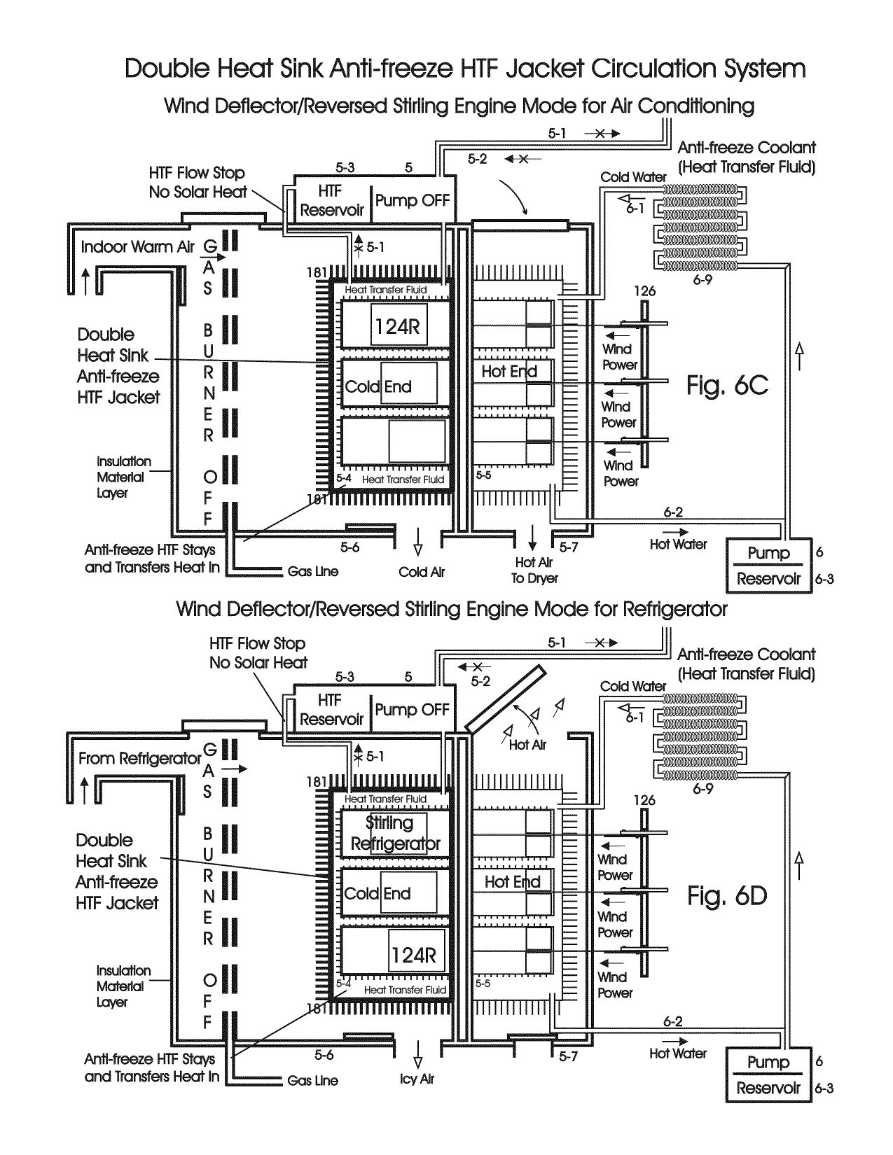

Now referring to FIGS. 6A-6D, at night and on overcast days, the solar collector is converted into wind deflector so the anti freeze heat transfer fluid pump stops, and no more high heated HTF passes a downstream conduit 5-2 that connects to the hot zone 2-1 of the multiple Stirling engines set 124S. But the anti-freeze HTF jacket 180 that surrounds the hot zone 2-1 is now full of the anti-freeze HTP. After the input of the kinetic energy from wind turbine 112, the engine switches from operating in Stirling cycle mode to operating in reversed Stirling cycle mode. Thus, the previous hot zone, a heat absorbing section of Stirling cycle, changes to a cold end and also a heat absorbing section of the reversed Stirling cycle. At the same time, the previous cold zone, a heat dissipating section of Stirling cycle, changes to a hot end, also a heat dissipating section of the reversed Stirling cycle. The cold end 2-1R of the reversed Stirling engine 124R includes an anti-freeze HTF jacket 180, an anti-freeze HTF jacket radiator type heat sink 181 (e.g., a heat absorbing device) with fins and/or other means of increasing the surface area that covers the cold end, a cold end enclosure 5-6 and a radiator type heat sink 5-4 (e.g., a heat absorbing device) with fins and/or other means of increasing the surface area that covers the cold end of the multiple reversed Stirling engines 124R. The warm air from the targeted area is driven into the cold end enclosure 5-6 and through the anti-freeze HTF jacket radiator type heat sink 181 that covers anti-freeze HTF jacket 180 surrounding the cold end and serves as a an air condition/refrigeration heat exchange area. The heat transfer fluid becomes an anti-freeze coolant that absorbs heat from outside environment through the outer heat sink 181 then transfer heat through the inner heat sink 5-4 into the cold end of the reversed Stirling engine 124R and to be pumped out from hot end. If the heat and electricity are needed at the same time, the auxiliary gas burner can add heat to the system to generate electricity and heat as a Combined Heat and Power unit (CHP) as shown in FIG. 6A or become a pure heat pump to pump the heat inside the dwelling as shown in FIG. 6B or an environmental control unit as shown in FIG. 6C, or for refrigeration as shown in FIG. 6D.

Another cooling agent circulation system having a semi-closed cycle includes rotary pump 6, conduits 6-1, 6-2, a water jacket 2-3 surrounding the hot end 2-2 of the multiple reversed Stirling engines 124R, a radiator type heat sink 5-5 of the hot end 2-2 of the same reversed Stirling engines, a hot end enclosure 5-7, and a radiator type heat sink 6-9 (e.g., a metal structure with fins) of the cooling agent upstream conduit 6-1 as shown in FIG. 4B and 6A-6D.

Referring to FIGS. 5A, 5B and 6A-6D, both Stirling cycle and reversed Stirling cycle mode share the same cooling process, in the illustrated example, the water jacket 2-3 surrounding the cold zone/hot end 2-2 of the multiple Stirling engines 124/reversed Stirling engine 124R includes a radiator type heat sink cooling system 5-5 with fins or other means of increasing the surface area that covers the cold zone/hot end 2-2 of the stacked Stirling engines 124. The radiator heat sink 5-5 transfers the heat to the cooling agent inside the water jacket 2-3 and the ambient air outside. Rotary water pump 6 circulates the cooling water from cold water reservoir 6-3 through cold water conduit 6-1 into the water jacket 2-3 of the multiple Stirling engines for cooling down the cold zone/hot end 2-2 of the multiple Stirling engines/reversed Stirling engine by heat exchange with the thermal energy within hot zone/cold end 2-1. The heated coolant (e.g., water) is returned to the cold water reservoir 6-3 through hot water conduit 6-2 The reservoir replenishes the cold water to the cold zone in Stirling mode and hot end in reversed Stirling mode (both have the same heat dissipation area). This can greatly reduce the temperature of the cold zone/hot end and further enhances the cooling process, thus increasing the power efficiency of the Stirling or reversed Stirling engines.

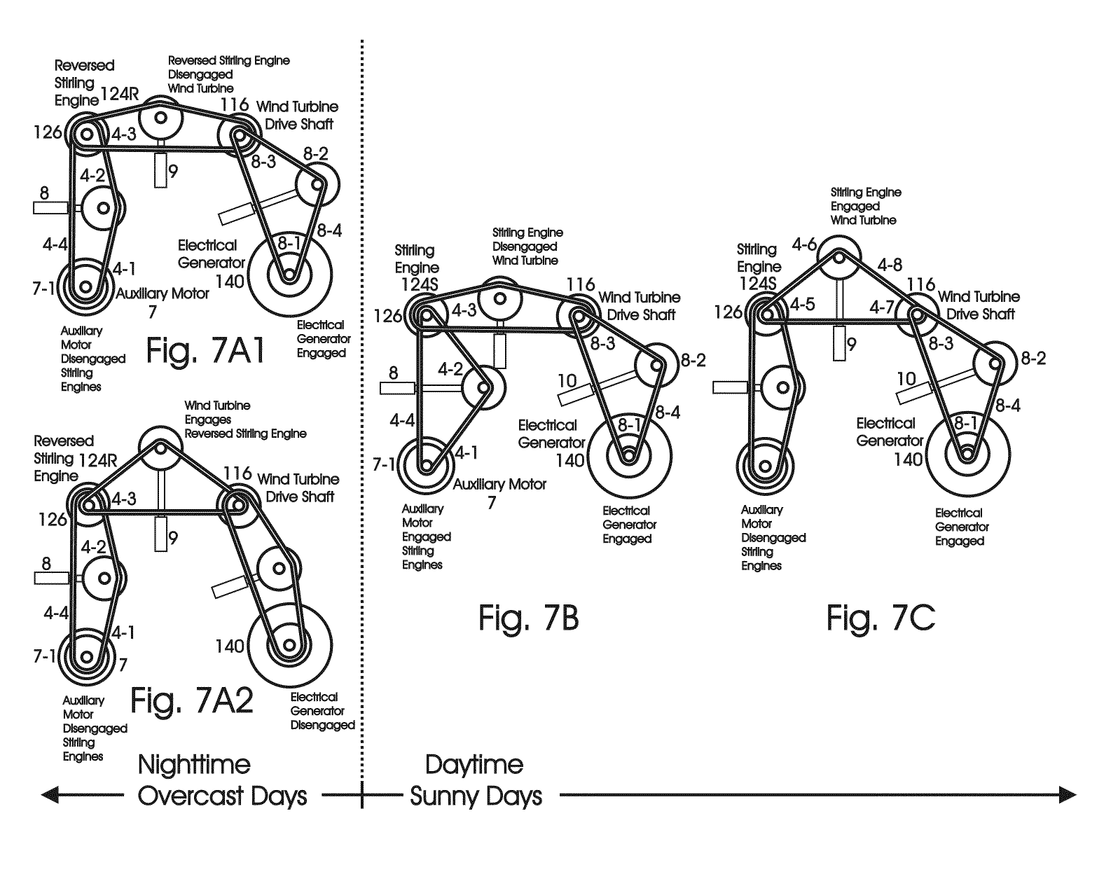

FIG. 7 shows two interconnection subsystem configurations during nighttime/overcast days and daytime/sunny days. Shaft 116 serves as the main drive shaft of the wind turbine 112, and shaft 126 serves as the main drive shaft of the Stirling engines/reversed Stirling engines 124S/124R. These two shafts can be coupled and decoupled by use of the engage/disengage electric motors 9.

FIG. 7A1 and FIG. 7A2 shows the disengagement position for the reversed Stirling engine driving shaft 126 with auxiliary motor 7 driving shaft 7-1 and the driving shaft 116 of the wind turbine 112 either couple with the reversed Stirling engine driving shaft 126 or couple with the driving shaft 136 of the electrical generator 140 so the wind turbine 112 rotates and the hybrid system 100 generates electricity solely from wind or serves for use with at least one of air-conditioning, refrigeration, space-heating and hot water supply during the nighttime/overcast days when the solar collector turns into wind collector and Stirling cycle also turns into reversed Stirling cycle.

Once the sun has risen, as shown in FIG. 7B, the wind deflector turns into solar collector, the HTF temperature reaches a set temperature (e.g., 150 Celsius), and the engage-disengage motor 8 is activated (e.g., by thermocouple) to retract and tighten one set of the V belt 4-4 on the pulleys 4-1, 4-2, 4-3. As shown in FIG. 7B, the drive shaft 7-1 of auxiliary starter motor 7 and jointed drive shaft 126 of Stirling engines 124S are now connected.

Soon after the HTF temperature reaches another set temperature (e.g., 175 Celsius), the thermocouple shuts off the auxiliary motor and activates the engage-disengage motor 8, which extends and loosens one set of the V belt 4-4 on the pulleys 4-1, 4-2, 4-3. As a result, drive shaft 7-1 of auxiliary motor 7 and drive shaft 126 of Stirling engines 124S become disconnected.

Once the sun heats the HTF temperature above another set temperature (e.g., 200 Celsius) and the Stirling engines start to rotate forcefully, the connection with the auxiliary motor is removed so that the second engage-disengage motor 9 in turn retracts and tightens another set of the V belt 4-8 on the pulleys 4-5, 4-6, 4-7. The drive shaft 116 of wind turbine 112 and jointed drive shaft 126 of the stacked Stirling engines 124S will be connected so that the driving force is transferred from the stacked Stirling engines 124S to the wind turbine, and then to electrical generator 140 since the wind turbine has been coupled with electrical generator 140 all the time except when the wind turbine couples with reversed Stirling engine 124R for environment control during nighttime and overcast days. The engage-disengage motor 10 and another set of the V belt 4-8 on the pulleys 4-5, 4-6, 4-7 interconnects drive shaft 126 of wind turbine 112 with drive shaft 136 of electrical generator 140 as shown in FIG. 7C.

In some examples, all six pulleys have large flanges to hold the v-shaped belt in the grooves when the belt is loose and slack as shown in the figures.

In the above mentioned embodiments, the solar collector 122 focuses sunrays towards the focal point or focal line of a solar absorber. At this focal point or focal line, the energy contained in the sun's rays is concentrated in a small area. In order to properly position the solar collectors to track the sun during its trajectory, a sun tracker unit (e.g., heliostat) can be used to cause directional changes of the solar collector 122 to aim the collector toward sun.

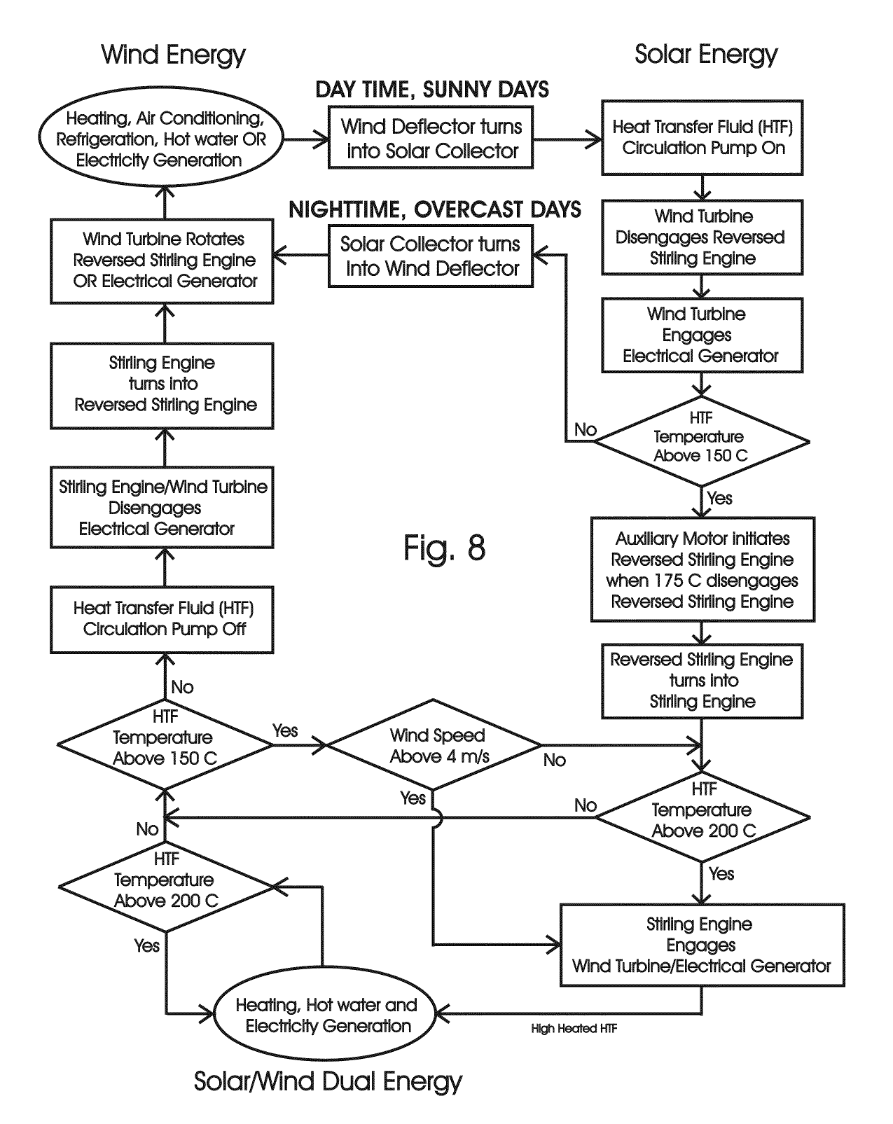

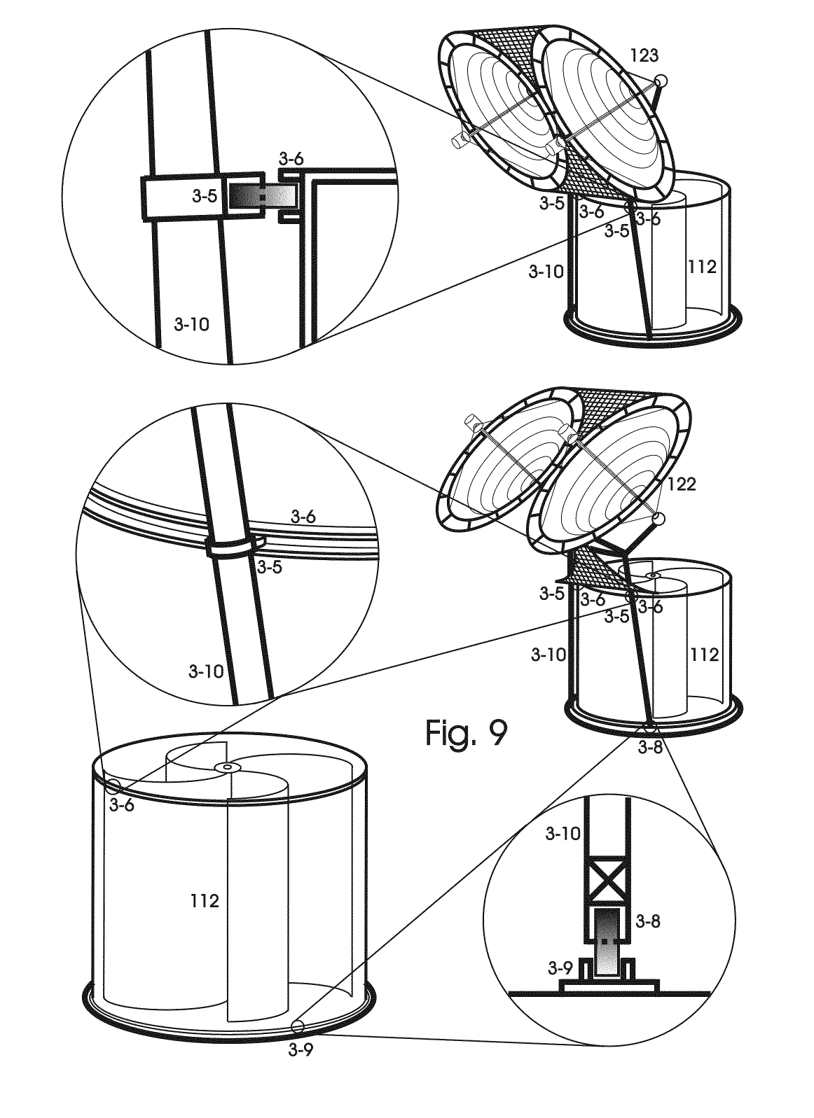

FIG. 8 shows a flow diagram of an operational procedure of one embodiment of the hybrid system 100 that derives its energy output from both wind and solar energy sources. As a result, the Stirling/reversed Stirling cycle engines and electrical generator operate in a complementary mode to dynamically utilize solar and wind energy in response to changing circumstances, thereby fully utilizing all available energy for use with at least one of air-conditioning, refrigeration, space-heating, hot water supply and electricity generation.

Solar Collector/Wind Deflector Structure for Use with Wind Turbines

Referring to FIG. 9, the circular solar collector/wind deflector structure is configured to be concentric with the main shaft of the wind turbine and to rotate mechanically about the same axis of the rotation of the wind turbine, for example, by mechanically coupling top horizontal rolling wheel 3-5 and bottom vertical rolling wheel 3-8 respectively to the top circular grove rail track 3-6 of the wind turbine 112 and the bottom circular grove rail track 3-9 on ground level with bracket support structure 3-10. The wind deflector structure can slide on a rail guide 3-6 on top and around the wind turbine 112 and this support will greatly reduce the stress of the whole supporting structure 3-10 under the wind load.

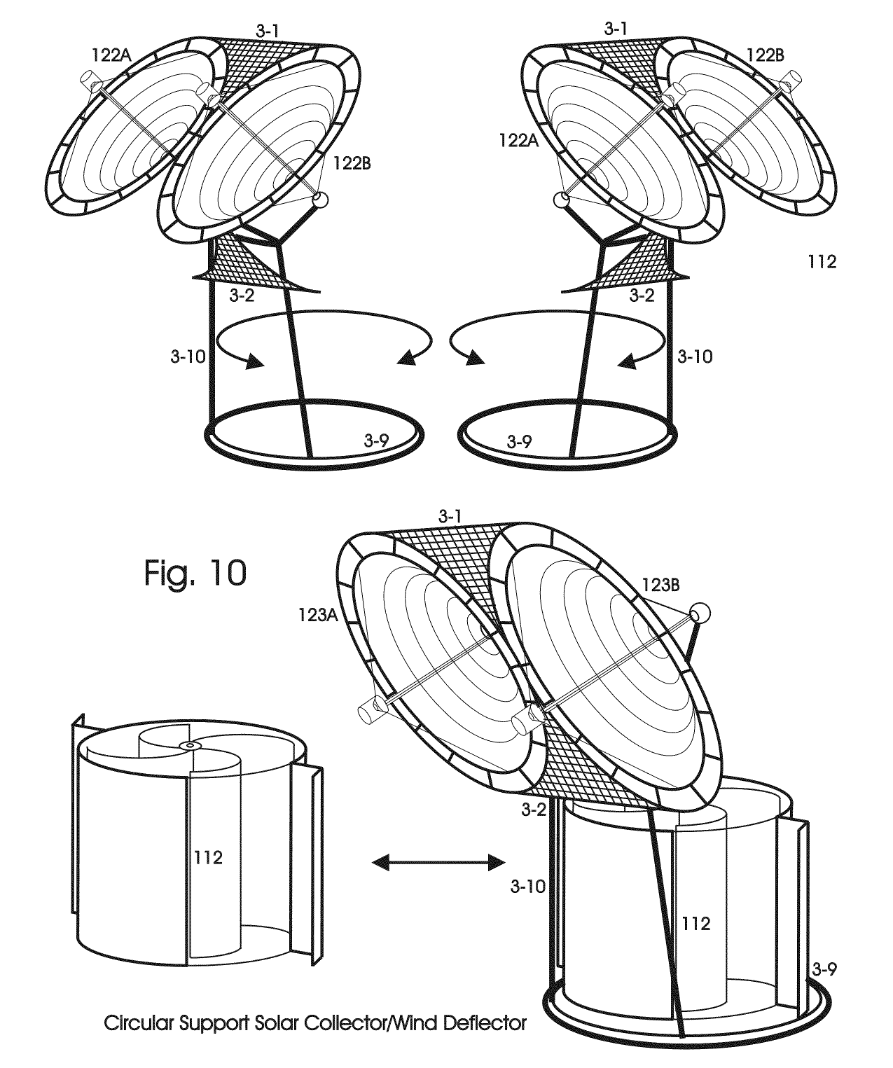

Now referring to FIG. 10, a dual solar collector 122A and 122B turns into wind deflector 123 structures for directing wind toward desired regions of the wind turbine 112. In this example, two sets of wind deflector 123A and deflectors 123B are positioned side by side over the wind turbine 112 and its supporting structure 3-10 rolls on the track 3-9 that is outside the periphery of the wind turbine 112 to direct the wind flow substantially towards only rotors or blades. Each wind deflector 123A and 123B also has an upper and lower triangle shape solar panel 3-1, 3-2 to fill in the gaps between two solar dishes. They can also deflect wind flow to the rotors so that the two solar dish/wind deflector can form an integrated rectangle shape to deflect more wind into the wind turbine at a more efficient shape. The wind deflectors 123 are mounted to a circular supporting structure 3-10 around the wind turbine 112 to coordinate the rotation of the wind turbine according to the wind direction, as shown in FIG. 10.

For some roof-mounted types as shown in FIG. 10, the solar collector/wind deflector supporting structure of a hybrid system can be wheel/track supported on top of a wind turbine to eliminate the excessive stress of wind load and rolling in the grove track on the ground.

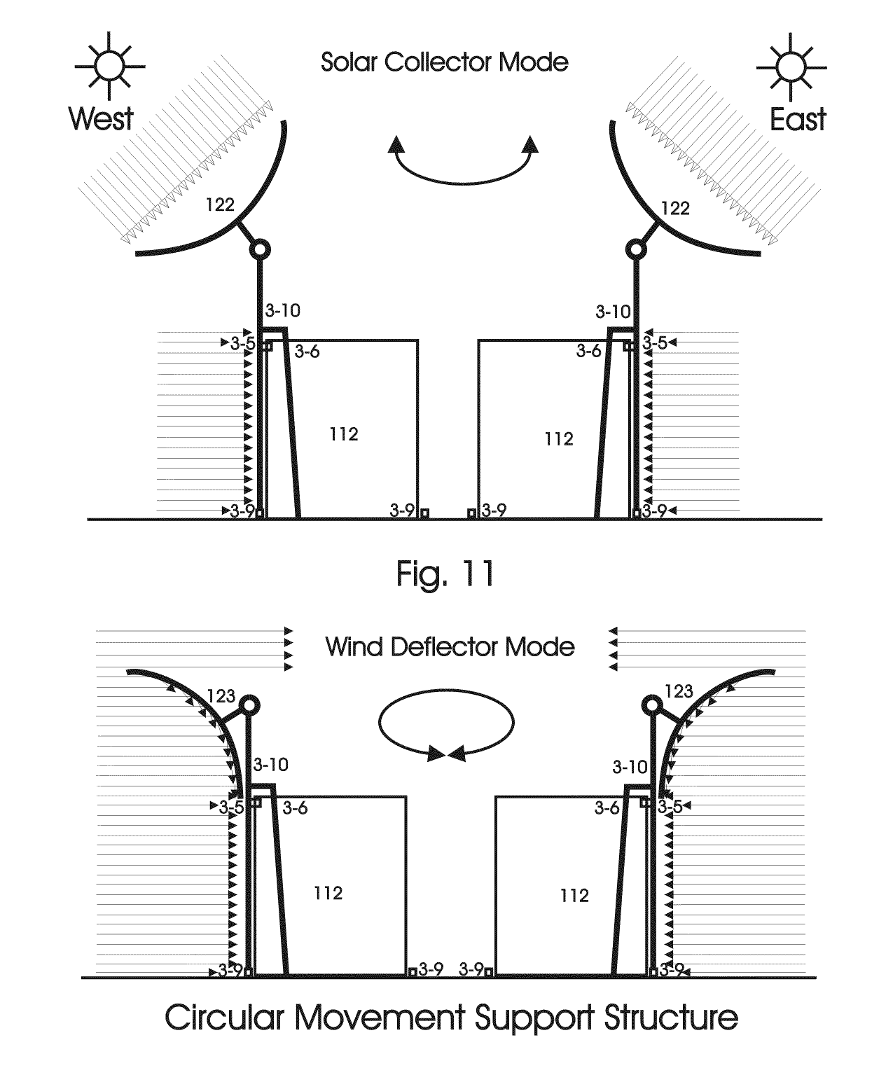

FIG. 11 shows the rotation of a wind turbine under wind and the swing of a solar collector from sunrise to sunset by use of a solar dish type circular movement solar collector/wind deflector structure. FIG. 11 also illustrates top horizontal rolling wheel 3-5 for mechanical coupling to the top circular grove rail track 3-6 of the wind turbine 112 and bottom vertical rolling wheel 3-8 mechanical coupling to the bottom circular grove rail track 3-9 on the ground level with bracket support structure 3-10. Also illustrated by FIG. 11 are two exchangeable modes of the polar pole solar collector/wind deflector structure that can be coupled to a wind turbine in response to changing environment.

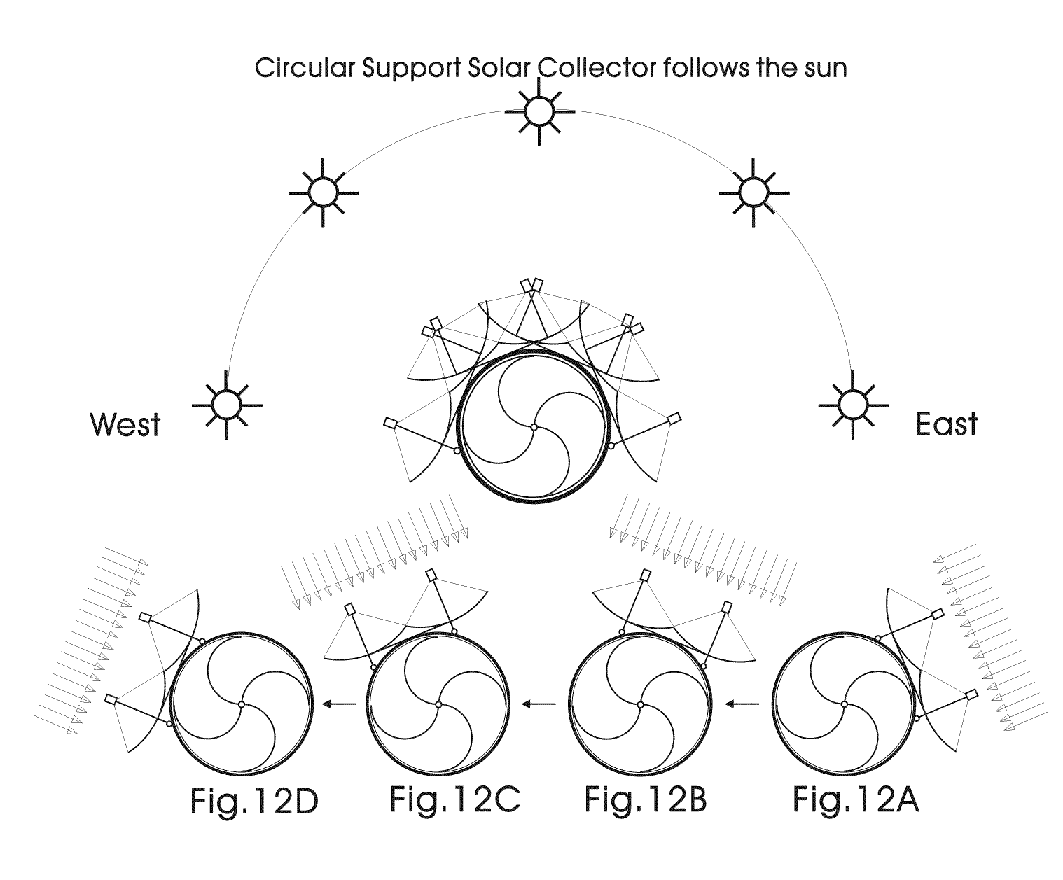

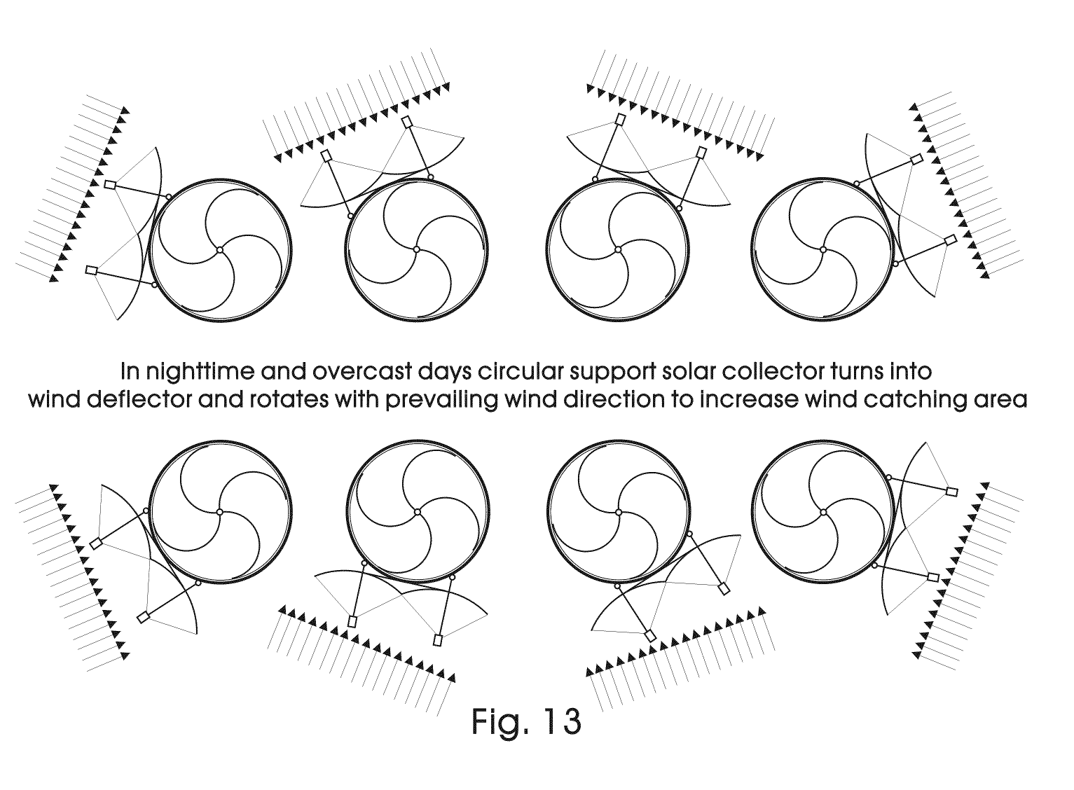

FIGS. 12A-12D show a top view of dual circular solar collectors of a hybrid solar and wind systems that illustrates the sequential movements of azimuth from sunrise to sunset. The servomotor driving mechanism rolls the circular solar collector along a track that circumscribes the axis of the supporting column.

Referring to FIG. 13, when air currents move towards the wind turbine 3 in various directions, the wind deflectors are mechanically moved by and aligned with the wind in the same balanced and angled position as shown in the figure. When wind flow changes direction, the wind deflector will rotate accordingly and always face the wind flow with substantially the same angle position. The wind deflector driving mechanisms further comprise a control module for generating the control signal for causing movement for controlling the circular rolling in response to environmental conditions. The environmental conditions include a wind condition, a sun condition, a temperature condition and the control module includes an anemometer, weather vane, one or more temperature sensors and thermostats.

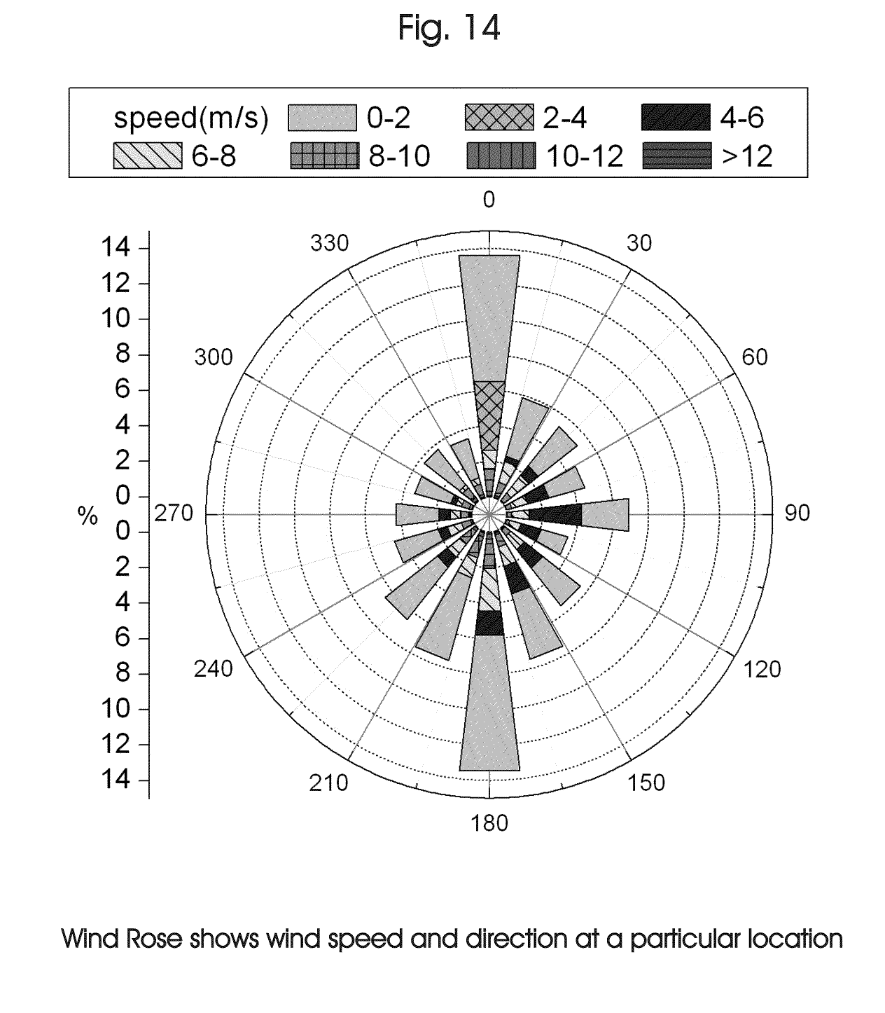

FIG. 14 shows examples of result of the Wind Rose plot as prevailing wind flow direction of daytime and nighttime are opposite (e.g., sea to land/land to sea and mountain to valley/valley to mountain).

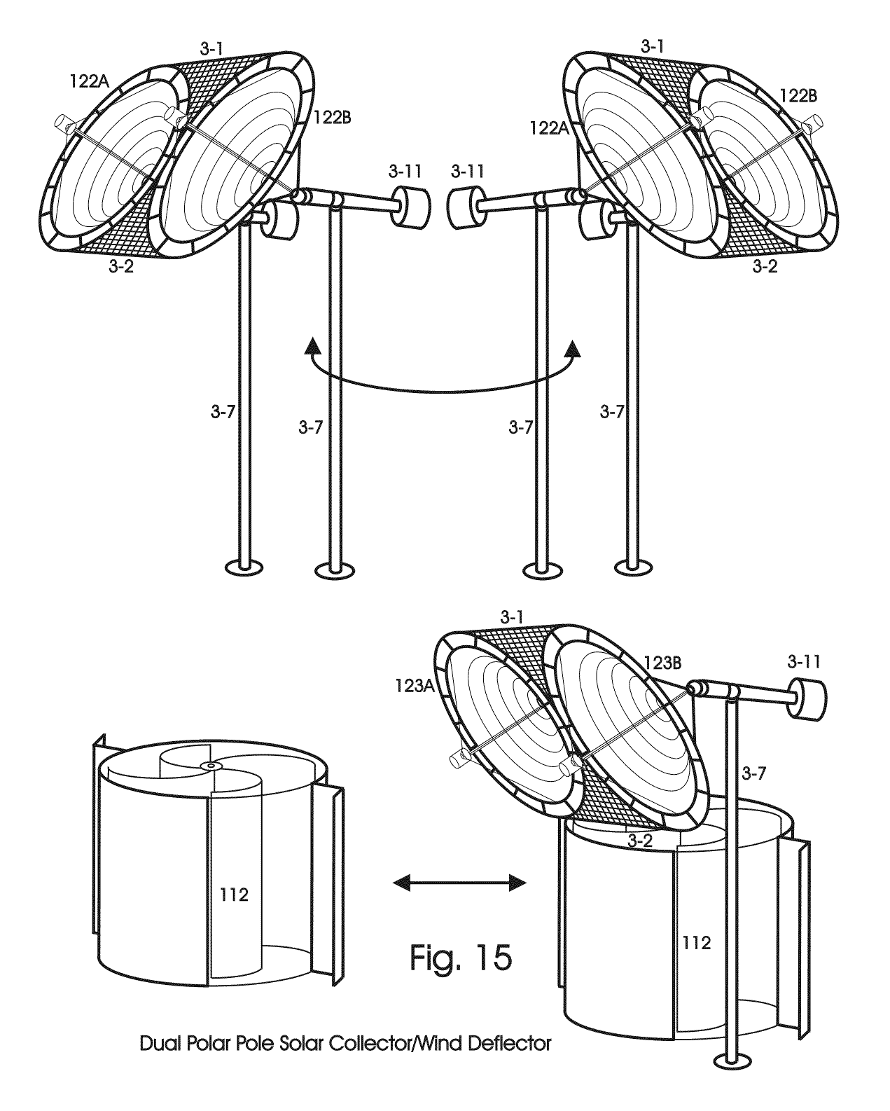

Now referring to FIG. 15, a dual solar collector 122A and 122B turns into wind deflector 123 structures for directing wind toward desired regions of the wind turbine 112. In this example, two sets of wind deflector 123A and 123B are used for directing wind toward desired regions of the wind turbine 112 and because most of time the wind flow direction changes oppositely during a day (e.g., sea to land/land to sea and mountain to valley/valley to mountain) as FIG. 14 Wind Rose plot shows, the dual wind deflector is configured to face most common wind direction to get the most efficient wind energy. In this example, two sets of wind deflector 123A and deflectors 123B are positioned side by side over the wind turbine 112 and its polar pole supporting structure 3-7 is configured outside the periphery of the wind turbine 112 to direct the wind flow substantially towards only rotors or blades. Each deflector also has an upper and lower triangle shape solar panel 3-1, 3-2 to fill in the gaps between two solar dishes. They can also deflect wind flow to the rotors so that the two solar dish/wind deflector can form an one-piece rectangle shape to deflect more wind into the wind turbine at a more efficient shape.

The two polar pole wind deflectors 3-7 with counterweight 3-11 are symmetrically mounted to both sides of the wind turbine 112 to coordinate the rotation of the wind turbine according to the direction of wind blow as shown in FIG. 15.

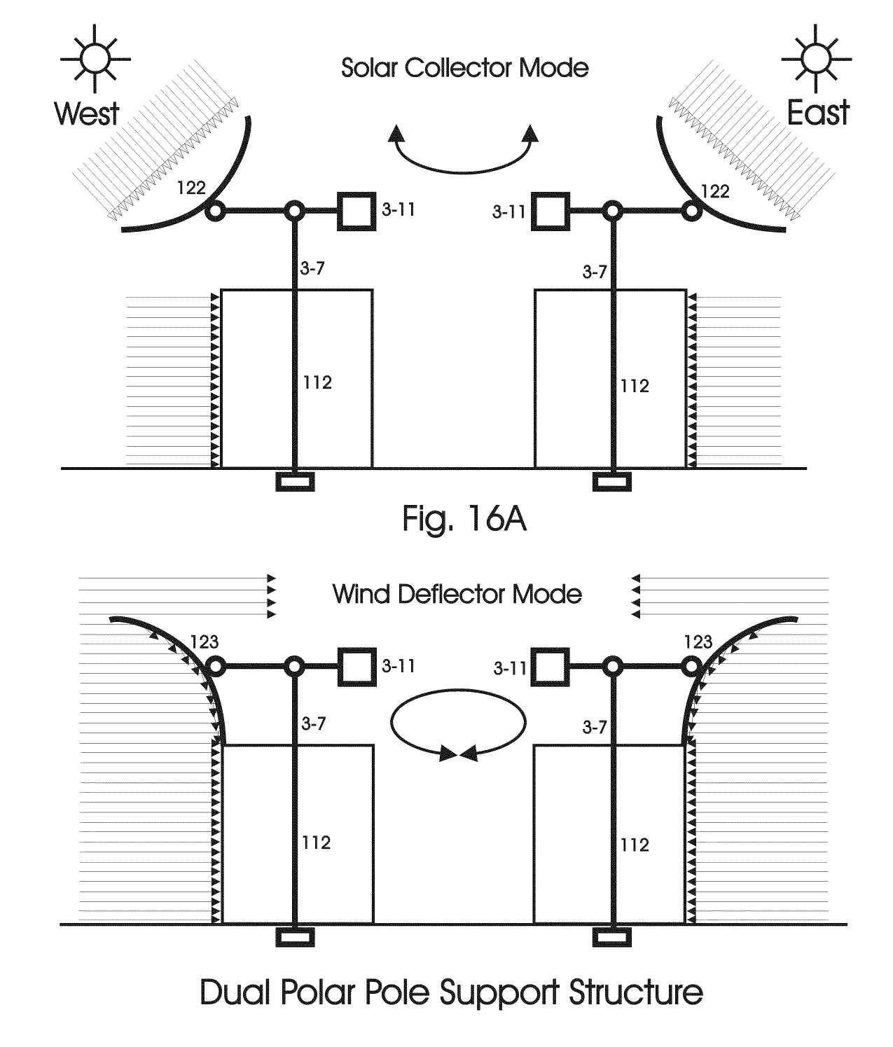

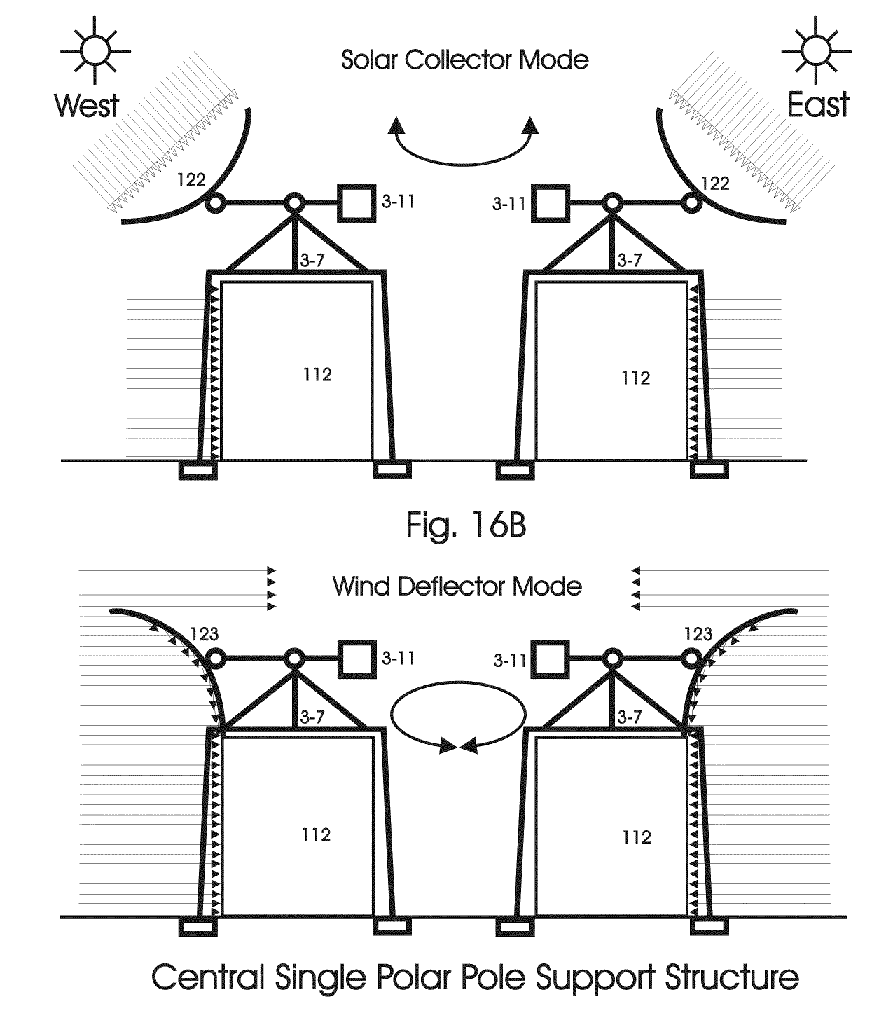

FIG. 16A shows the rotation of a wind turbine 112 under wind and the swing of a solar collector 122 from sunrise to sunset by use of a solar dish type polar pole supporting structure 3-7 with a counterweight 3-11. It also illustrates two exchangeable modes of the polar pole solar collector/wind deflector structure that can be coupled to a wind turbine in response to changing environment. There is another type of central single polar pole supporting structure as shown in FIG. 16B.

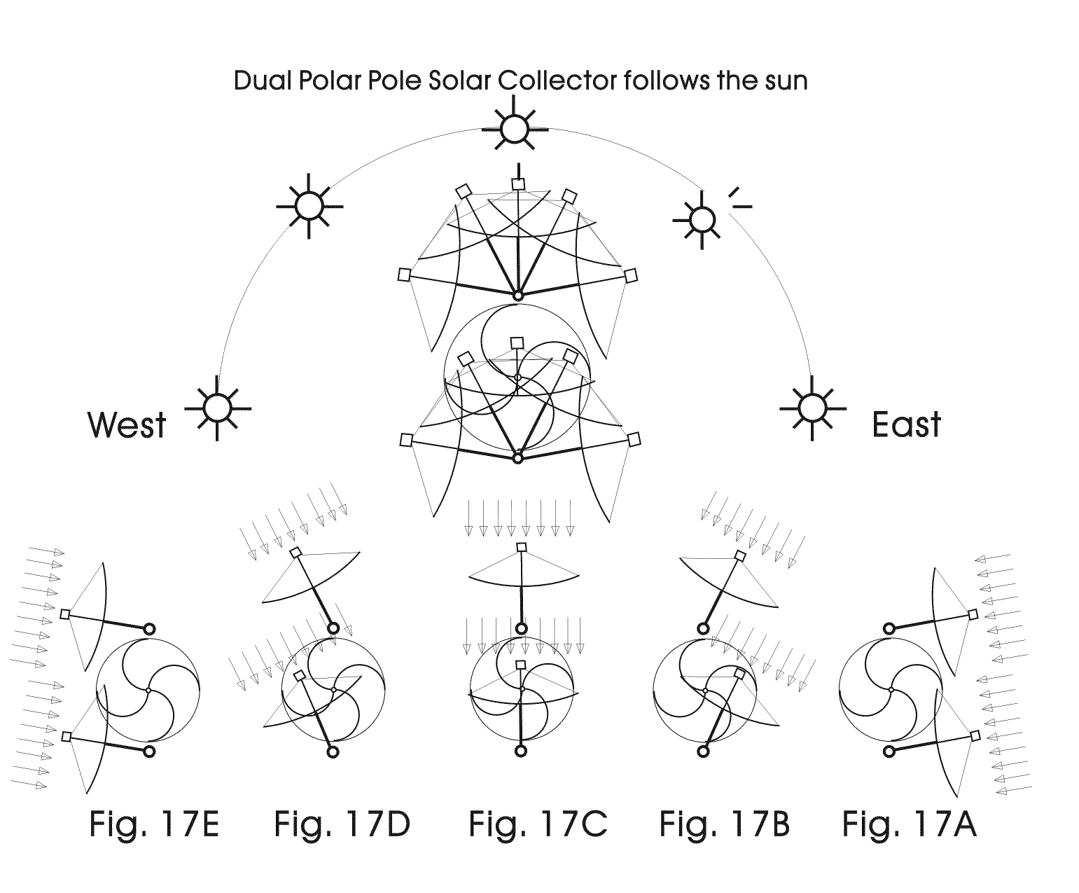

FIGS. 17A-17E show a top view of dual polar pole solar collectors of a hybrid solar and wind systems that illustrates the sequential movements of azimuth from sunrise to sunset. The servomotor driving mechanisms moves the solar collector around the axis of the supporting column.

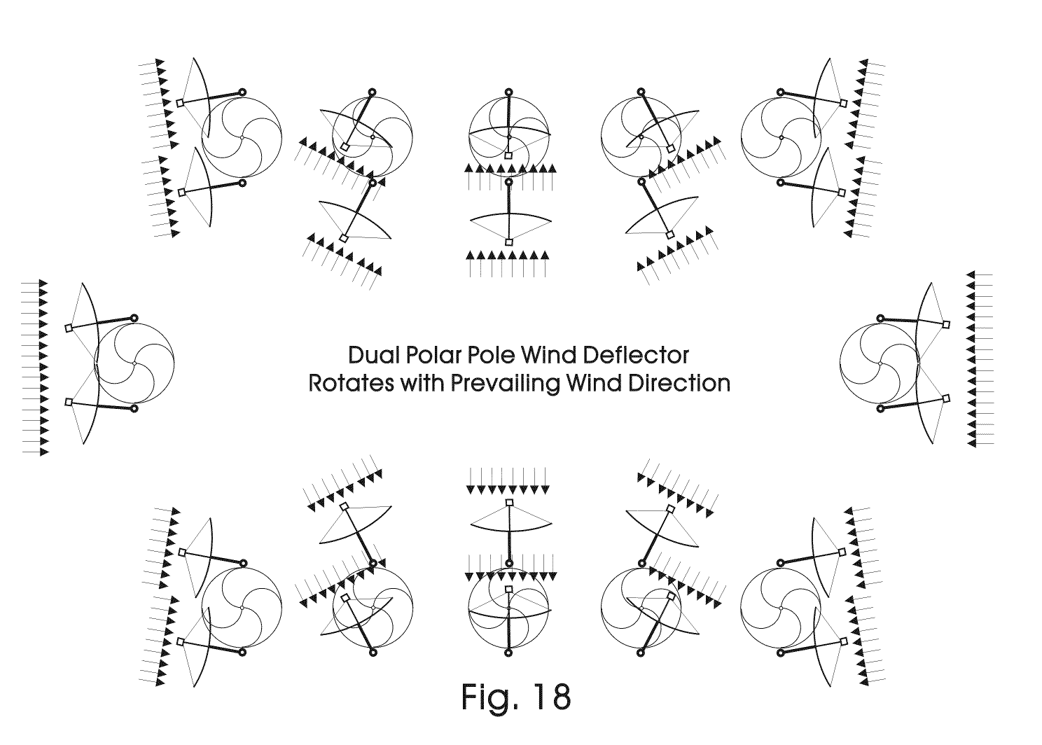

Referring to FIG. 18, when air currents move towards the wind turbine in various directions, the wind deflectors are mechanically moved by and aligned with the wind in the same balanced and angled position. When wind flow changes direction, the wind deflector will rotate accordingly and always face the wind flow with substantially the same angle position. The wind deflector driving mechanisms further comprise a control module for generating the control signal for causing movement for rotating around the polar pole axis in response to environmental conditions. The environmental conditions include a wind condition, a sun condition, a temperature condition and the control module includes an anemometer, weather vane, one or more temperature, motion and position sensors and thermostats.

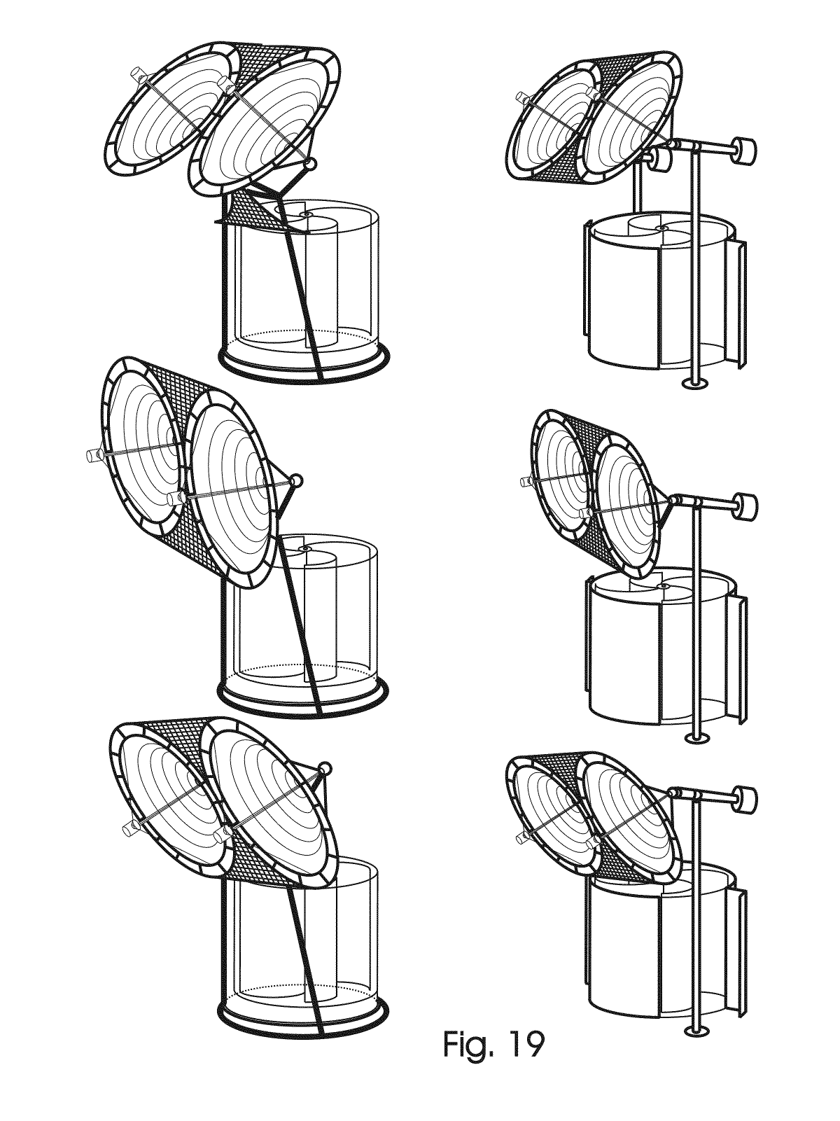

FIG. 19 shows three operational positions of two kinds of supporting structures. The solar collector/wind deflector can be placed on circular movement supporting structure or dual polar pole supporting structures at both sides of the wind turbine.

### Extensions and Applications

There can be many applications in which the systems and methods described above can be useful. For instance, during daytime and sunny days, in addition to producing electricity, the hybrid system (or some parts of the hybrid system) can also convert solar energy to thermal energy to furnish hot water supply and space heating for offices or residences. Another instance, during nighttime and overcast days, in addition to producing electricity, the hybrid system (or some parts of the hybrid system) can also convert wind energy to supply air condition/refrigeration or thermal energy to furnish hot water supply and space heating for offices or residences.

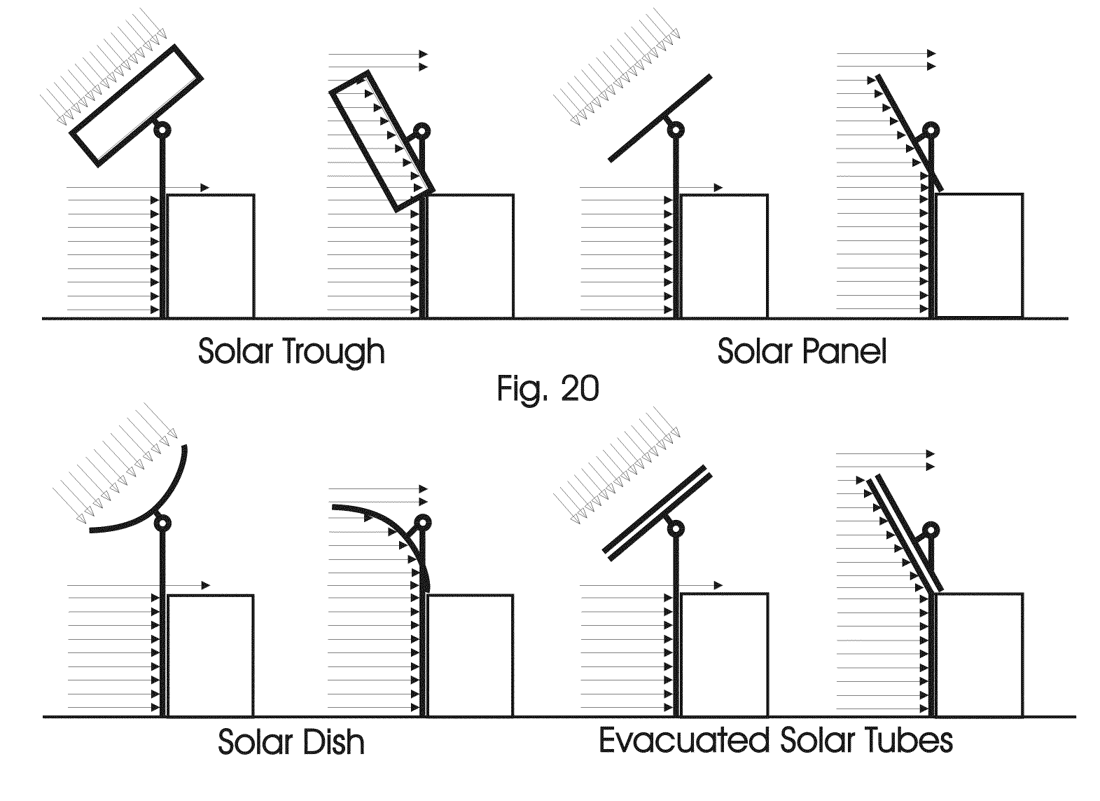

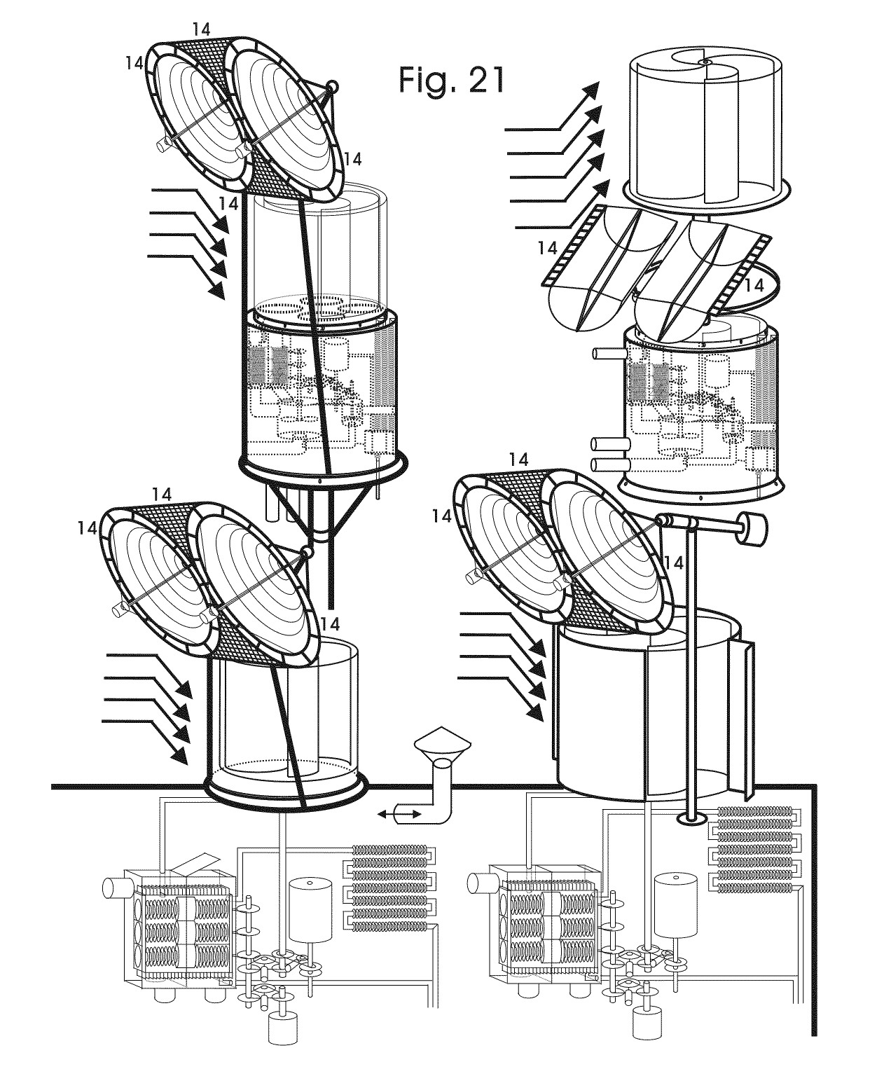

FIG. 20 shows various types of solar collectors may be deployed in the hybrid system 100, including a solar dish, a solar trough, a solar panel and solar evacuated tubes.

FIG. 21 shows that the system 100 can be mounted on a high tower, one or more supporting poles, and possibly other freestanding structures and with different kinds of solar collectors. For some standing types, the solar collector/wind deflector, for instance, a compound parabolic collector (CPC) trough permits much wider sunrays receiving angle and efficient collection can be mounted either on top or beneath the wind turbine so that the turbine rotor would not be obstructed from direct access to prevailing wind. FIG. 21 also shows a set of solar panels 14 can utilize the sun tracking function and generate the extra electricity to power the electric requirements of the system. The generated currents can be combined via electrical coupling. This invention utilizes low profile vertical axis wind turbine with compact and integrated solar collector/wind deflector structure self-contained in small footprint

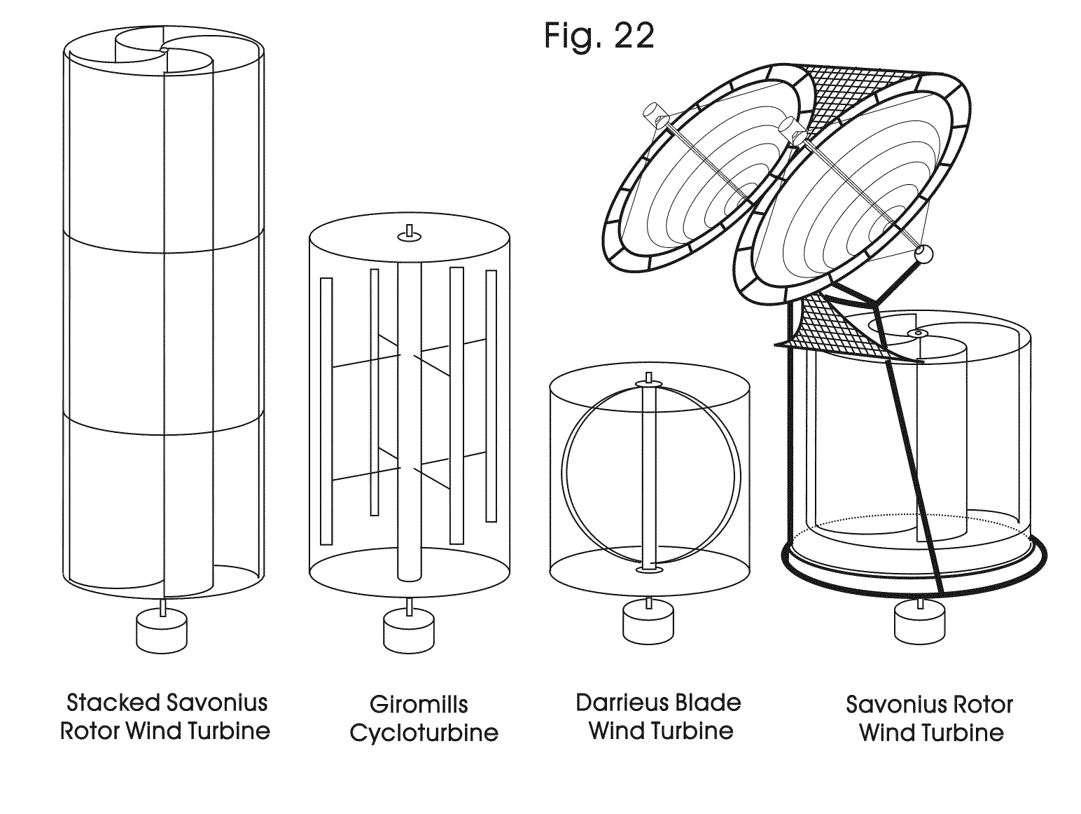

FIG. 22 shows examples of various types of vertical axis wind turbines that can be used in the hybrid systems, including Darrieus blade type turbine, Savonius blade type turbine, Giromills Cycloturbine, and others. Other types of wind turbines can also be used.

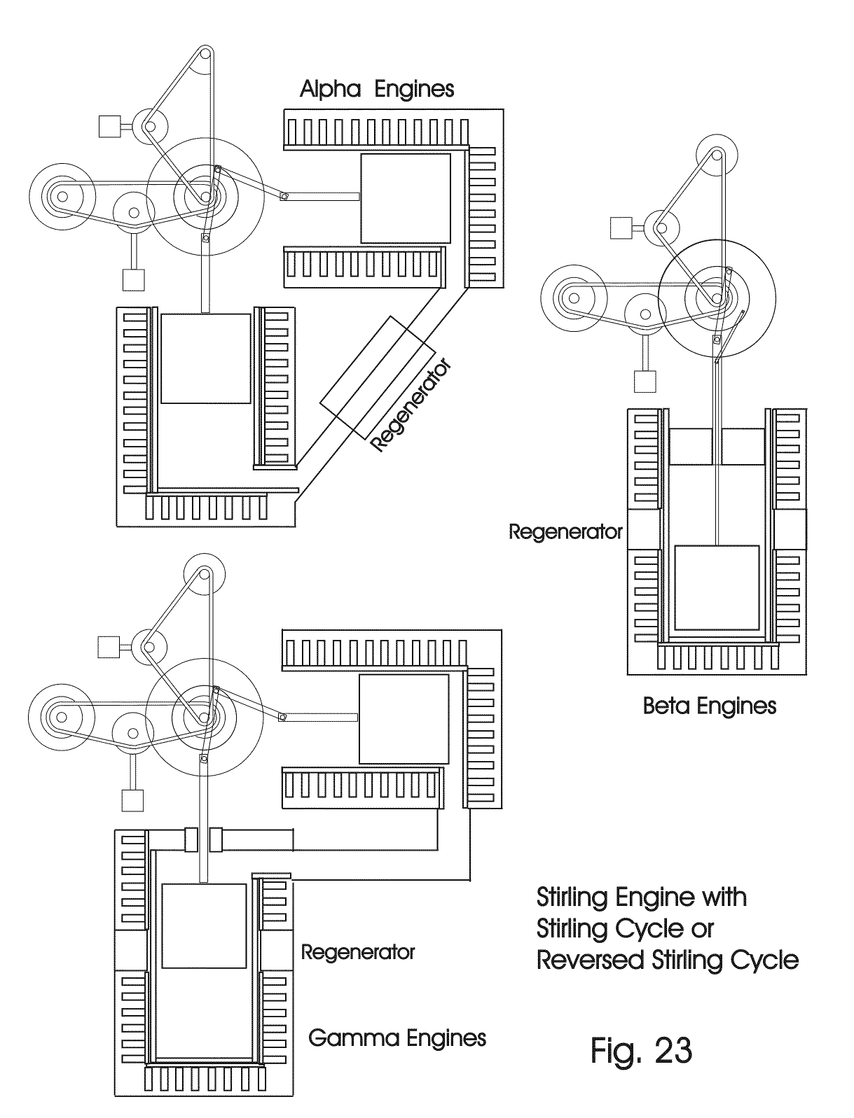

FIG. 23 shows examples of three types of Stirling engines that can be used in the hybrid systems, including Alpha engines, Beta engines and Gamma engines. These engines are distinguished by the way that they move the air between the hot and cold zones of the cylinder. Other types of Stirling engines or thermo-mechanical engines can also be used.

In some implementations, solar collectors are made of high strength, durable, non-corrosive, shock absorbent, vibration dampening and lightweight advanced composite (glass fiber and carbon fiber) structures. Also, advanced composite (carbon fiber and Kevlar fiber) airfoils, blades or vanes are used in the wind turbine to generate electricity. The hybrid system can achieve and maintain high operational efficiencies with lightweight and substantially reduced manufacturing and maintenance cost. In addition, because of the structure simplicity of construction and light weighted with composites, it can be affordable for small commercial office building rooftop, parking lot and house rooftop or backyard electricity generating application. Furthermore, the system can be used to meet household/small business energy demands in both urban and suburban areas at a cost affordable even by developing countries.

It is to be understood that the foregoing description is intended to illustrate and not to limit the scope of the invention, which is defined by the scope of the appended claims. Other embodiments are within the scope of the following claims.

Having described the invention, and a preferred embodiment thereof, what we claim as new and secured by letters patent is:

1. An apparatus for converting solar and/or wind energy for powering an electrical generator and/or a thermo-mechanical engine, said apparatus comprising:
a hybrid-powered subsystem including a wind-powered subsystem and a solar-powered subsystem,
said wind-powered subsystem including:
a rotor for receiving wind to generate mechanical energy;
a convertible structure that transitions between being a wind deflector and being a solar collector; and
a driving mechanism for the convertible structure; and
a first shaft for providing a mechanical coupling for the rotor to transfer the generated mechanical energy; and
said solar-powered subsystem including:
a solar collector for receiving solar energy to generate thermal energy;
a solar collector-supporting frame structure;
stacked thermo-mechanical engines with exchangeable thermo-mechanical engine/reversed thermo-mechanical engines mode either coupled to the wind-powered subsystem for selectively converting the mechanical energy generated by the wind-powered subsystem into energy for controlling temperature in a space or coupled to the solar collector for converting the generated thermal energy into mechanical energy; and
a second shaft mechanically coupled to the thermo-mechanical engine/reversed thermo-mechanical engines;
a third shaft mechanically coupled to an electrical generator;
an interconnection subsystem configured for disengageably coupling a pair of shafts, wherein the pair of shafts is selected from the group consisting of
the first shaft and the second shaft, and
the first shaft and the third shaft.

2. The apparatus of claim 1, wherein the solar powered subsystem further comprises a pair of polar pole support structures mounted adjacent to a periphery of said rotor of said wind powered subsystem.

3. The apparatus of claim 1, wherein the solar powered subsystem further comprises a circular rolling supporting rail track structure mounted around a periphery of said rotor of said wind powered subsystem.

4. The apparatus of claim 2, wherein the polar pole support structure comprises:
a first single polar column member positioned adjacent to a periphery of said rotor; and
a second single polar column member positioned adjacent to a periphery of said rotor diametrically opposite from said first single polar column member.

5. The apparatus of claim 4, wherein the polar pole support structure further comprises:
a first horizontal support beam mounted on top of the first vertical polar pole support structure, said first horizontal support beam having a swivel at an outside edge thereof to cause said solar collector to rotate horizontally and/or vertically; and
a first counter weight at an opposite end of the first horizontal support beam to counter balance said solar collector to rotate horizontally and/or vertically;
a second horizontal support beam mounted on top of the second vertical polar pole support structure, said second horizontal support beam having a swivel at an outside edge thereof, said solar collector to rotate horizontally and/or vertically; and
a second counter weight at an opposite end of the second horizontal support beam to counter balance said solar collector to rotate horizontally and/or vertically;
wherein said first and second single polar pole support and horizontal beam structure cooperate to direct wind flow toward a desired region of the rotor in response to changes in wind direction.

6. The apparatus of claim 3, wherein the circular rolling supporting rail track structure comprises a solar collector-supporting frame structure that is mounted for orbital travel through a circular path extending horizontally.

7. The apparatus of claim 6, wherein the solar collector-supporting frame structure further comprises:
a horizontally rotating azimuth circular rail track mounts;
vertical frames on each side that hold elevation trunnions for the solar collector and integral solar absorber/driving mechanisms thereof; and
a horizontal layout rolling wheel that moves in a grove rail on top of and around the wind turbine to reduce stress of wind load on the supporting frame.

8. The apparatus of claim 1, wherein the solar powered subsystem comprises circulation systems for respectively circulating anti-freeze heat transfer fluid through a heat absorbing section during operation in the thermo-mechanical engine mode, and cooling agent through a heat dissipating section during operation in the thermo-mechanical engine mode and reversed thermo-mechanical mode.

9. The apparatus of claim 8, wherein the circulation system comprises
a thermally insulated closed loop circulation system;
a radiator type double heat sink anti-freeze heat transfer fluid jacket;
a fluid reservoir for containing the anti-freeze heat transfer fluid; and
a pump for pumping the anti-freeze heat transfer fluid contained in the fluid reservoir
through a first conduit toward a heat source to be heated and subsequently
through a second conduit toward a heat absorbing section of the thermo-mechanical engine,
whereby said anti-freeze heat transfer fluid exchanges heat in the heat absorbing section of the thermo-mechanical engine when the pump is on and in Stirling engine mode; and
wherein when said pump is off and the system is in reversed Stirling engine mode the anti-freeze heat transfer fluid stops flowing and stays in a radiator type double heat sink anti-freeze heat transfer fluid jacket surrounding the heat absorbing section and transfers heat into the heat absorbing section of the reversed Stirling engine from outside a targeted area,
said radiator type double heat sink being configured to prevent accumulation of ice and frost on said heat sink.

10. The apparatus of claim 1, wherein the solar powered subsystem further comprises a set of one or more solar panels coupled to the solar collector for generating additional electricity to power one or more power consumption devices.

11. The apparatus of claim 10, wherein at least one of the solar panels comprises triangular wind deflectors to cover top and bottom sections of gaps between two joined solar dishes.

12. The apparatus of claim 1, wherein the interconnection subsystem comprises a set of pulleys and one or more V-belts for selectively coupling the set of pulleys.

13. The apparatus of claim 1, wherein the interconnection subsystem further comprises one of a mechanical clutch, an electromagnetic clutch, and variator clutch.

14. The apparatus of claim 1, further comprising a control module for generating a control signal for causing movement for controlling said interconnection system, wind powered subsystem, solar powered subsystem and said convertible structure in response to environmental conditions.

15. The apparatus of claim 14, wherein said control module is configured to respond to environmental conditions that include a wind condition.

16. The apparatus of claim 14, wherein said control module is configured to respond to environmental conditions that include an extent of solar illumination.

17. The apparatus of claim 14, wherein said control module is configured to respond to environmental conditions that include a temperature.

18. The apparatus of claim 14, wherein said control module comprises an anemometer, weather vane, and one or more temperature, motion and position sensors and thermostats.

19. The apparatus of claim 1, wherein the solar powered subsystem further comprises a solar tracking component for obtaining measurements of the sun's rays and for directing the solar collector to a desired orientation relative to the sun's rays based on the obtained measurements.

20. The apparatus of claim 1, wherein the solar powered subsystem further comprises a second circulation system for circulating cooling agent to maintain a low temperature of the heat dissipating section, said heat dissipating section being a cold zone in thermo-mechanical engine mode and a hot end in reversed thermo-mechanical engine mode.
